(19) United States
(12) Patent Application Publication
(10) Pub. No.: US 2013/0087199 A1
(43) Pub. Date: Apr. 11, 2013

(54) Electronic Device Module Comprising Long Chain Branched (LCB), Block or Interconnected Copolymers of Ethylene and Optionally Silane

(71) Applicants: John A. Naumovitz, Midland, MI (US); Debra H. Neimann, Lake Jackson, TX (US); Rajen M. Patel, Lake Jackson, TX (US); Shaofu Wu, Sugar Land, TX (US)

(72) Inventors: John A. Naumovitz, Midland, MI (US); Debra H. Neimann, Lake Jackson, TX (US); Rajen M. Patel, Lake Jackson, TX (US); Shaofu Wu, Sugar Land, TX (US)

(21) Appl. No.: 13/703,639

(22) PCT Filed: Jun. 15, 2011
(86) PCT No.: PCT/US11/40489

§ 371 Date: Dec. 12, 2012

Related U.S. Application Data
(60) Provisional application No. 61/358,065, filed on Jun. 24, 2010.

(51) Int. Cl. H01L 31/0203; H05K 1/03

(52) U.S. Cl. CPC H01L 31/0203; H05K 1/032
USPC 136/259; 361/746

(57) ABSTRACT

An electronic device module is disclosed comprising:
A. at least one electronic device, and
B. a polymeric material in intimate contact with at least one surface of the electronic device, the polymeric material comprising
(1) An ethylenic polymer comprising at least 0.1 amyl branches per 1000 carbon atoms as determined by Nuclear Magnetic Resonance and both a highest peak melting temperature, Tₘ, in ° C., and a heat of fusion, H_{f}, in J/g, as determined by DSC Crystallinity, where the numerical values of Tₘ and H_{f} correspond to the relationship:

Tₘ≧(0.2143*H_{f})+79.643,

and wherein the ethylenic polymer has less than about 1 mole percent ctane comonomer, and less than about 0.5 mole percent ctane, pentene, or ctane comonomer.
(2) optionally, free radical initiator or a photoinitiator in an amount of at least about 0.05 wt % based on the weight of the copolymer, (3) optionally, a co-agent in an amount of at least about 0.05 wt % based upon the weight of the copolymer, and (4) optionally, a vinyl silane compound.

### CROSS REFERENCE TO RELATED APPLICATION

This application claims priority from U.S. provisional application Ser, No. 61/358,065, filed Jun. 24, 2010, which is incorporated herein by reference in its entirety. This application is related to U.S. application Ser. No. 11/857,195 filed on Sep. 18, 2007, and U.S. application Ser. No. 12/402,789 filed on Mar. 12, 2009.

### FIELD OF THE INVENTION

This invention relates to electronic device modules. In one aspect, the invention relates to electronic device modules comprising an electronic device, e.g., a solar or photovoltaic (PV) cell, and a protective polymeric material while in another aspect, the invention relates to electronic device modules in which the protective polymeric material is an ethylenic polymer comprising at least 0.1 amyl branches per 1000 carbon atoms as determined by Nuclear Magnetic Resonance and both a highest peak melting temperature, Tₘ, in ° C., and a heat of fusion, H_{f}, in J/g, as determined by DSC Crystallinity, where the numerical values of Tₘ and H_{f} correspond to the relationship:

Tₘ>(0.2143*H_{f})+79.643, preferably Tₘ>(0.2143*H_{f})+81

and wherein the ethylenic polymer has less than about 1 mole percent hexene comonomer, and less than about 0.5 mole percent butene, pentene, or octene comonomer, preferably less than about 0.1 mole percent butene, pentene, or octene comonomer.

The ethylenic polymer can also have a heat of fusion of less than about 170 J/g and/or a peak melting temperature of the ethylenic polymer of less than 126° C. Preferably the ethylenic polymer comprises no appreciable methyl and/or propyl branches as determined by Nuclear Magnetic Resonance. The ethylenic polymer preferably comprises no greater than 2.0 units of amyl groups per 1000 carbon atoms as determined by Nuclear Magnetic Resonance. In yet another aspect, the invention relates to a method of making an electronic device module.

### BACKGROUND OF THE INVENTION

Polymeric materials are commonly used in the manufacture of modules comprising one or more electronic devices including, but not limited to, solar cells (also known as photovoltaic cells), liquid crystal panels, electro-luminescent devices and plasma display units. The modules often comprise an electronic device in combination with one or more substrates, e.g., one or more glass cover sheets, often positioned between two substrates in which one or both of the substrates comprise glass, metal, plastic, rubber or another material. The polymeric materials are typically used as the encapsulant or sealant for the module or depending upon the design of the module, as a skin layer component of the module, e.g., a backskin in a solar cell module. Typical polymeric materials for these purposes include silicone resins, epoxy resins, polyvinyl butyral resins, cellulose acetate, ethylene-vinyl acetate copolymer (EVA) and ionomers.

United States Patent Application Publication 2001/0045229 A1 identifies a number of properties desirable in any polymeric material that is intended for use in the construction of an electronic device module. These properties include (i) protecting the device from exposure to the outside environment, e.g., moisture and air, particularly over long periods of time (ii) protecting against mechanical shock, (iii) strong adhesion to the electronic device and substrates, (iv) easy processing, including sealing, (v) good transparency, particularly in applications in which light or other electromagnetic radiation is important, e.g., solar cell modules, (vi) short cure times with protection of the electronic device from mechanical stress resulting from polymer shrinkage during cure, (vii) high electrical resistance with little, if any, electrical conductance, and (viii) low cost. No one polymeric material delivers maximum performance on all of these properties in any particular application, and usually trade-offs are made to maximize the performance of properties most important to a particular application, e.g., transparency and protection against the environment, at the expense of properties secondary in importance to the application, e.g., cure time and cost. Combinations of polymeric materials are also employed, either as a blend or as separate components of the module.

EVA copolymers with a high content (28 to 35 wt %) of units derived from the vinyl acetate monomer are commonly used to make encapsulant film for use in photovoltaic (PV) modules. See, for example, WO 95/22844, 99/04971, 99/05206 and 2004/055908. EVA resins are typically stabilized with ultra-violet (UV) light additives, and they are typically crosslinked during the solar cell lamination process using peroxides to improve heat and creep resistance to a temperature between about 80 and 90° C. However, EVA resins are less than ideal PV cell encapsulating film material for several reasons. For example, EVA film progressively darkens in intense sunlight due to the EVA resin chemically degrading under the influence of UV light. This discoloration can result in a greater than 30% loss in power output of the solar module after as little as four years of exposure to the environment. EVA resins also absorb moisture and are subject to decomposition.

Moreover and as noted above, EVA resins are typically stabilized with UV additives and crosslinked during the solar cell lamination and/or encapsulation process using peroxides to improve heat resistance and creep at high temperature, e.g., 80 to 90° C. However, because of the C═O bonds in the EVA molecular structure that absorbs UV radiation and the presence of residual peroxide crosslinking agent in the system after curing, an additive package is used to stabilize the EVA against UV-induced degradation. The residual peroxide is believed to be the primary oxidizing reagent responsible for the generation of chromophores (e.g., U.S. Pat. No. 6,093,757). Additives such as antioxidants, UV-stabilizers, UV-absorbers and others are can stabilize the EVA, but at the same time the additive package can also block UV-wavelengths below 360 nanometers (nm).

Photovoltaic module efficiency depends on photovoltaic cell efficiency and the sun light wavelength passing through the encapsulant. One of the most fundamental limitations on the efficiency of a solar cell is the band gap of its semi-conducting material, i.e., the energy required to boost an electron from the bound valence band into the mobile conduction band. Photons with less energy than the band gap pass through the module without being absorbed. Photons with energy higher than the band gap are absorbed, but their excess energy is wasted (dissipated as heat). In order to increase the photovoltaic cell efficiency, “tandem” cells or multi-junction cells are used to broaden the wavelength range for energy conversion. In addition, in many of the thin film technologies such as amorphous silicon, cadmium telluride, or copper indium gallium selenide, the band gap of the semi-conductive materials is different than that of mono-crystalline silicon. These photovoltaic cells will convert light into electricity for wavelength below 360 nm. For these photovoltaic cells, an encapsulant that can absorb wavelengths below 360 nm is needed to maintain the PV module efficiency.

U.S. Pat. Nos. 6,320,116 and 6,586,271 teach another important property of these polymeric materials, particularly those materials used in the construction of solar cell modules. This property is thermal creep resistance, i.e., resistance to the permanent deformation of a polymer over a period of time as a result of temperature. Thermal creep resistance, generally, is directly proportional to the melting temperature of a polymer. Solar cell modules designed for use in architectural application often need to show excellent resistance to thermal creep at temperatures of 90° C. or higher. For materials with low melting temperatures, e.g., EVA, crosslinking the polymeric material is often necessary to give it higher thermal creep resistance.

Crosslinking, particularly chemical crosslinking, while addressing one problem, e.g., thermal creep, can create other problems. For example, EVA, a common polymeric material used in the construction of solar cell modules and which has a rather low melting point, is often crosslinked using an organic peroxide initiator. While this addresses the thermal creep problem, it creates a corrosion problem, i.e., total crosslinking is seldom, if ever, fully achieved and this leaves residual peroxide in the EVA. This remaining peroxide can promote oxidation and degradation of the EVA polymer and/or electronic device, e.g., through the release of acetic acid over the life of the electronic device module. Moreover, the addition of organic peroxide to EVA requires careful temperature control to avoid premature crosslinking.

Another potential problem with peroxide-initiated crosslinking is the buildup of crosslinked material on the metal surfaces of the process equipment. During extrusion runs, high residence time is experienced at all metal flow surfaces. Over longer periods of extrusion time, crosslinked material can form at the metal surfaces and require cleaning of the equipment. The current practice to minimize gel formation, i.e., this crosslinking of polymer on the metal surfaces of the processing equipment, is to use low processing temperatures which, in turn, reduces the production rate of the extruded product.

One other property that can be important in the selection of a polymeric material for use in the manufacture of an electronic device module is thermoplasticity, i.e., the ability to be softened, molded and formed. For example, if the polymeric material is to be used as a backskin layer in a frameless module, then it should exhibit thermoplasticity during lamination as described in U.S. Pat. No. 5,741,370. This thermoplasticity, however, must not be obtained at the expense of effective thermal creep resistance.

### SUMMARY OF THE INVENTION

In one embodiment, the invention is an electronic device module comprising:
A. At least one electronic device, and
B. A polymeric material in intimate contact with at least one surface of the electronic device, the polymeric material comprising (1) the specified polymers described below, (2) optionally, free radical initiator, e.g., a peroxide or azo compound, or a photoinitiator, e.g., benzophenone, in an amount of at least about 0.05 wt % based on the weight of the copolymer, (3) optionally, a co-agent in an amount of at least about 0.05 wt % based upon the weight of the copolymer, and (4) optionally a vinyl silane.

In another embodiment, the invention is an electronic device module comprising:
A. At least one electronic device, and
B. A polymeric material in intimate contact with at least one surface of the electronic device, the polymeric material comprising (1) the specified polymers described below, (2) optionally, a vinyl silane, e.g., vinyl tri-ethoxy silane or vinyl tri-methoxy silane, in an amount of at least about 0.1 wt % based on the weight of the copolymer, (3) free radical initiator, e.g., a peroxide or azo compound, or a photoinitiator, e.g., benzophenone, in an amount of at least about 0.05 wt % based on the weight of the copolymer, and (4) optionally, a co-agent in an amount of at least about 0.05 wt % based on the weight of the copolymer.

“In intimate contact” and like terms mean that the polymeric material is in contact with at least one surface of the device or other article in a similar manner as a coating is in contact with a substrate, e.g., little, if any gaps or spaces between the polymeric material and the face of the device and with the material exhibiting good to excellent adhesion to the face of the device. After extrusion or other method of applying the polymeric material to at least one surface of the electronic device, the material typically forms and/or cures to a film that can be either transparent or opaque and either flexible or rigid. If the electronic device is a solar cell or other device that requires unobstructed or minimally obstructed access to sunlight or to allow a user to read information from it, e.g., a plasma display unit, then that part of the material that covers the active or “business” surface of the device is highly transparent.

The module can further comprise one or more other components, such as one or more glass cover sheets, and in these embodiments, the polymeric material usually is located between the electronic device and the glass cover sheet in a sandwich configuration. If the polymeric material is applied as a film to the surface of the glass cover sheet opposite the electronic device, then the surface of the film that is in contact with that surface of the glass cover sheet can be smooth or uneven, e.g., embossed or textured.

Typically, the polymeric material is an ethylene-based polymer The polymeric material can fully encapsulate the electronic device, or it can be in intimate contact with only a portion of it, e.g., laminated to one face surface of the device. Optionally, the polymeric material can further comprise a scorch inhibitor, and depending upon the application for which the module is intended, the chemical composition of the copolymer and other factors, the copolymer can remain uncrosslinked or be crosslinked. If crosslinked, then it is crosslinked such that it contains less than about 85 percent xylene soluble extractables as measured by ASTM 2765-95.

In another embodiment, the invention is the electronic device module as described in the two embodiments above except that the polymeric material in intimate contact with at least one surface of the electronic device is a co-extruded material in which at least one outer skin layer (i) does not contain peroxide for crosslinking, and (ii) is the surface which comes into intimate contact with the module. Typically, this outer skin layer exhibits good adhesion to glass. This outer skin of the co-extruded material can comprise any one of a number of different polymers, but is typically the same polymer as the polymer of the peroxide-containing layer but without the peroxide. This embodiment of the invention allows for the use of higher processing temperatures which, in turn, allows for faster production rates without unwanted gel formation in the encapsulating polymer due to extended contact with the metal surfaces of the processing equipment. In another embodiment, the extruded product comprises at least three layers in which the skin layer in contact with the electronic module is without peroxide, and the peroxide-containing layer is a core layer.

In another embodiment, the invention is a method of manufacturing an electronic device module, the method comprising the steps of:
A. Providing at least one electronic device, and
B. Contacting at least one surface of the electronic device with a polymeric material comprising (1) the specified polymers described below, (2) optionally, free radical initiator, e.g., a peroxide or azo compound, or a photoinitiator, e.g., benzophenone, in an amount of at least about 0.05 wt % based on the weight of the copolymer, (3) optionally, a co-agent in an amount of at least about 0.05 wt % based upon the weight of the copolymer, and (4) optionally a vinyl silane.

In another embodiment the invention is a method of manufacturing an electronic device, the method comprising the steps of:
A. Providing at least one electronic device, and
B. Contacting at least one surface of the electronic device with a polymeric material comprising (1) the specified polymers described below, (2) optionally, a vinyl silane, e.g., vinyl tri-ethoxy silane or vinyl tri-methoxy silane, in an amount of at least about 0.1 wt % based on the weight of the copolymer, (3) free radical initiator, e.g., a peroxide or azo compound, or a photoinitiator, e.g., benzophenone, in an amount of at least about 0.05 wt % based on the weight of the copolymer, and (4) optionally, a co-agent in an amount of at least about 0.05 wt % based on the weight of the copolymer.

In a variant on both of these two method embodiments, the module further comprises at least one translucent cover layer disposed apart from one face surface of the device, and the polymeric material is interposed in a sealing relationship between the electronic device and the cover layer. “In a sealing relationship” and like terms mean that the polymeric material adheres well to both the cover layer and the electronic device, typically to at least one face surface of each, and that it hinds the two together with little, if any, gaps or spaces between the two module components (other than any gaps or spaces that may exist between the polymeric material and the cover layer as a result of the polymeric material applied to the cover layer in the form of an embossed or textured film, or the cover layer itself is embossed or textured).

Moreover, in both of these method embodiments, the polymeric material can further comprise a scorch inhibitor, and the method can optionally include a step in which the copolymer is crosslinked, e.g., either contacting the electronic device and/or glass cover sheet with the polymeric material under crosslinking conditions, or exposing the module to crosslinking conditions after the module is formed such that the polyolefin copolymer contains less than about 70 percent xylene soluble extractables as measured by ASTM 2765-95. Crosslinking conditions include heat (e.g., a temperature of at least about 160° C.), radiation (e.g., at least about 15 mega-rad if by E-beam, or 0.05 joules/cm² if by UV light), moisture (e.g., a relative humidity of at least about 50%), etc.

In another variant on these method embodiments, the electronic device is encapsulated, i.e., fully engulfed or enclosed, within the polymeric material. In another variant on these embodiments, the glass cover sheet is treated with a silane coupling agent, e.g., (-amino propyl tri-ethoxy silane). In yet another variant on these embodiments, the polymeric material further comprises a graft polymer to enhance its adhesive property relative to the one or both of the electronic device and glass cover sheet. Typically the graft polymer is made in situ simply by grafting the polyolefin copolymer with an unsaturated organic compound that contains a carbonyl group, e.g., maleic anhydride.

### Specified Polymers Description

In one embodiment, the polymeric material is an ethylene/non-polar α-olefin polymeric film characterized in that the film has (i) greater than or equal to (≧) 92% transmittance over the wavelength range from 400 to 1100 nanometers (nm), and (ii) a water vapor transmission rate (WVTR) of less than (<) about 50, preferably <about 15, grams per square meter per day (g/m²-day) at 38° C. and 100% relative humidity (RH).

In another embodiment, the polymeric material comprises at least 0.1 amyl branches per 1000 carbon atoms as determined by Nuclear Magnetic Resonance and both a highest peak melting temperature, Tₘ, in ° C., and a heat of fusion, H_{f}, in J/g, as determined by DSC Crystallinity, where the numerical values of Tₘ and H_{f} correspond to the relationship:

Tₘ≧(0.2143*H_{f})+79.643, preferably Tₘ≧(0.2143*H_{f})+81

and wherein the ethylenic polymer has less than about 1 mole percent hexene comonomer, and less than about 0.5 mole percent butene, pentene, or octene comonomer, preferably less than about 0.1 mole percent butene, pentene, or octene comonomer.

The ethylenic polymer can have a heat of fusion of less than about 170 J/g and/or a peak melting temperature of the ethylenic polymer of less than 126° C. Preferably the ethylenic polymer comprises no appreciable methyl and/or propyl branches as determined by Nuclear Magnetic Resonance. The ethylenic polymer preferably comprises no greater than 2.0 units of amyl groups per 1000 carbon atoms as determined by Nuclear Magnetic Resonance.

In another embodiment, the polymeric material comprises at least one preparative TREF fraction that elutes at 95° C. or greater using a Preparative Temperature Rising Elution Fractionation method, where at least one preparative TREF fraction that elutes at 95° C. or greater has a branching level greater than about 2 methyls per 1000 carbon atoms as determined by Methyls per 1000 Carbons Determination on P-TREF Fractions, and where at least 5 weight percent of the ethylenic polymer elutes at a temperature of 95° C. or greater based upon the total weight of the ethylenic polymer.

In another embodiment, the polymeric material comprises at least one preparative TREF fraction that elutes at 95° C. or greater using a Preparative Temperature Rising Elution Fractionation method, where at least one preparative TREF fraction that elutes at 95° C. or greater has a g′ value of less than 1, preferably less than 0.95, as determined by g′ by 3D-GPC, and where at least 5 weight percent of the ethylenic polymer elutes at a temperature of 95° C. or greater based upon the total weight of the ethylenic polymer.

In another embodiment, the polymeric material comprises at least one preparative TREF fraction that elutes at 95° C. or greater using a Preparative Temperature Rising Elution Fractionation method, where at least one preparative TREF fraction that elutes at 95° C. or greater has a gpcBR value greater than 0.05 and less than 5 as determined by gpcBR Branching Index by 3D-GPC, and where at least 5 weight percent of the ethylenic polymer elutes at a temperature of 95° C. or greater based upon the total weight of the ethylenic polymer.

In another embodiment, the polymeric material comprises at least one preparative TREF fraction that elutes at 90° C. or greater using a Preparative Temperature Rising Elution Fractionation method, where at least one preparative TREF fraction that elutes at 90° C. or greater has a branching level greater than about 2 methyls per 1000 carbon atoms as determined by Methyls per 1000 Carbons Determination on P-TREF Fractions, and where at least 7.5 weight percent of the ethylenic polymer elutes at a temperature of 90° C. or greater based upon the total weight of the ethylenic polymer.

In another embodiment, the polymeric material comprises at least one preparative TREF fraction that elutes at 90° C. or greater using a Preparative Temperature Rising Elution Fractionation method, where at least one preparative TREF fraction that elutes at 90° C. or greater has a g′ value of less than 1, preferably less than 0.95, as determined by g′ by 3D-GPC, and where at least 7.5 weight percent of the ethylenic polymer elutes at a temperature of 90° C. or greater based upon the total weight of the ethylenic polymer.

In another embodiment, the polymeric material comprises at least one preparative TREF fraction that elutes at 90° C. or greater using a Preparative Temperature Rising Elution Fractionation method, where at least one preparative TREF fraction that elutes at 90° C. or greater has a gpcBR value greater than 0.05 and less than 5 as determined by gpcBR Branching Index by 3D-GPC, and where at least 7.5 weight percent of the ethylenic polymer elutes at a temperature of 90° C. or greater based upon the total weight of the ethylenic polymer.

### BRIEF DESCRIPTION OF THE DRAWINGS

FIG. 1 is a schematic illustrating the steps of formation of the ethylenic polymer for use in the photovoltaic films of the invention.

FIG. 2 is a plot of a relationship between density and heat of fusion for 30 Commercially Available Resins of low density polyethylene (LDPE).

FIG. 3 is a plot of heat flow versus temperature as determined by DSC Crystallinity analysis for Example 1, Comparative Example 1 (CE 1), and Polymer 2 (LP2).

FIG. 4 is a plot of heat flow versus temperature as determined by DSC Crystallinity analysis of Example 2, Comparative Example 1 (CE 1), and Polymer 1 (LP1).

FIG. 5 is a plot of temperature versus weight percent of polymer sample eluted as determined by Analytical Temperature Rising Elution Fractionation analysis of Example 1 and Comparative Example 1.

FIG. 6 is a plot of temperature versus weight percent of polymer sample eluted as determined by Analytical Temperature Rising Elution Fractionation analysis of Example 2, Comparative Example 1, and Polymer LP1.

FIG. 7 is a plot of maximum peak melting temperature versus heat of fusion for Examples 1-5, Comparative Examples 1 and 2, and Commercially Available Resins 1-31, and a linear demarcation between the Examples, the Comparative Examples, and the Commercially Available Resins.

FIG. 8 represents the temperature splits for Fractions A-D using the Preparative Temperature Rising Elution Fractionation method on Example 3.

FIG. 9 represents the temperature splits for combined Fractions AB and CD of Example 3.

FIG. 10 represents the weight percentage of Fraction AB and CD for Example 3-5.

FIG. 11 is a plot of methyls per 1000 carbons (corrected for chain ends) versus weight average elution temperature as determined by Methyls per 1000 Carbons Determination on P-TREF Fractions analysis of Fractions AB and CD for Examples 3-5.

FIG. 12 represents a schematic of a cross-fractionation instrument for performing Cross-Fractionation by TREF analysis.

FIGS. 13(a & b) and (c & d) are 3D and 2D infra red (IR) response curves for weight fraction eluted versus log molecular weight and ATREF temperature using the Cross-Fractionation by TREF method. FIGS. 13(a & b) represent a 33:67 weight percent physical blend of Polymer 3 and Comparative Example 2. FIGS. 13(c & d) represent 3D & 2D views, respectively, for an IR response curve of Example 5. FIG. 13(a) and (b) show discrete components for the blend sample, while FIG. 13(c) and (d) show a continuous fraction (with no discrete components).

FIG. 14 is a schematic of one embodiment of an electronic device module of this invention, i.e., a rigid photovoltaic (PV) module.

FIG. 15 is a schematic of another embodiment of an electronic device module of this invention, i.e., a flexible PV module.

### DESCRIPTION OF THE PREFERRED EMBODIMENTS

Currently, when a high crystallinity, ethylene-based polymer is used with a low crystallinity, highly long chain branched ethylene-based polymer, there is no mechanical means to create a blend that faithfully combines all the physical performance advantages of the ethylene-based polymer with the all the favorable processing characteristics of the highly long chain branched ethylene-based polymer. Disclosed are compositions and methods that address this shortcoming.

In order to achieve an improvement of physical properties over and above a mere physical blend of a ethylene-based polymer with a highly branched ethylene-based polymer, it was found that bonding the two separate constituents—an ethylene-based polymer and a highly long chain branched ethylene-based polymer—results in an ethylenic polymer material with physical properties akin to or better than the ethylene-based polymer component while maintaining processability characteristics akin to the highly long chain branched ethylene-based polymer component. It is believed that the disclosed ethylenic polymer structure is comprised of highly branched ethylene-based polymer substituents grafted to or free-radical polymerization generated ethylene-based long chain polymer branches originating from a radicalized site on the ethylene-based polymer. The disclosed composition is an ethylenic polymer comprised of an ethylene-based polymer with long chain branches of highly long chain branched ethylene-based polymer.

The combination of physical and processing properties for the disclosed ethylenic polymer is not observed in mere blends of ethylene-based polymers with highly long chain branched ethylene-based polymers. The unique chemical structure of the disclosed ethylenic polymer is advantageous as the ethylene-based polymer and the highly long chain branched ethylene-based polymer substituent are linked. When bonded, the two different crystallinity materials produce a polymer material different than a mere blend of the constituents. The combination of two different sets of branching and crystallinity materials results in an ethylenic polymer with physical properties that are better than the highly long chain branched ethylene-based polymer and better processability than the ethylene-based polymer.

The melt index of the disclosed ethylenic polymer may be from about 0.01 to about 1000 g/10 minutes, as measured by ASTM 1238-04 (2.16 kg and 190° C.).

Ethylene-Based Polymers

Suitable ethylene-based polymers can be prepared with Ziegler-Natta catalysts, metallocene or vanadium-based single-site catalysts, or constrained geometry single-site catalysts. Examples of linear ethylene-based polymers include high density polyethylene (HDPE) and linear low density polyethylene (LLDPE). Suitable polyolefins include, but are not limited to, ethylene/diene interpolymers, ethylene/α-olefin interpolymers, ethylene homopolymers, and blends thereof.

Suitable heterogeneous linear ethylene-based polymers include linear low density polyethylene (LLDPE), ultra low density polyethylene (ULDPE), and very low density polyethylene (VLDPE). For example, some interpolymers produced using a Ziegler-Natta catalyst have a density of about 0.89 to about 0.94 g/em³ and have a melt index (I₂) from about 0.01 to about 1,000 W10 minutes, as measured by ASTM 1238-04 (2.16 kg and 190° C.). Preferably, the melt index (I₂) is from about 0.1 to about 50 g/10 minutes. Heterogeneous linear ethylene-based polymers may have a molecular weight distributions, M_{w}/Mₙ, from about 3.5 to about 4.5.

The linear ethylene-based polymer may comprise units derived from one or more α-olefin copolymers as long as there is at least 50 mole percent polymerized ethylene monomer in the polymer.

High density polyethylene (HDPE) may have a density in the range of about 0.94 to about 0.97 g;/cm³. HDPE is typically a homopolymer of ethylene or an interpolymer of ethylene and low levels of one or more α-alefin copolymers. HDPE contains relatively few branch chains relative to the various copolymers of ethylene and one or more α-olefin copolymers. HDPE can be comprised of less than 5 mole % of the units derived from one or more α-olefin comonomers

Linear ethylene-based polymers such as linear low density polyethylene and ultra low density polyethylene (ULDPE) are characterized by an absence of long chain branching, in contrast to conventional low crystallinity, highly branched ethylene-based polymers such as LDPE. Heterogeneous linear ethylene-based polymers such as LLDPE can be prepared via solution, slurry, or gas phase polymerization of ethylene and one or more α-olefin comonomers in the presence of a Ziegler-Natta catalyst, by processes such as are disclosed in U.S. Pat. No. 4,076,698 (Anderson, et al.). Relevant discussions of both of these classes of materials, and their methods of preparation are found in U.S. Pat. No. 4,950,541 (Tabor, et al.).

An α-alefin comonomer may have, for example, from 3 to 20 carbon atoms.

Preferably, the α-alefin comonomer may have 3 to 8 carbon atoms. Exemplary α-alefin comonomers include, but are not limited to, propylene, 1-butene, 3-methyl-1-butene, 1-pentene, 3-methyl-1-pentene, 4-methyl-1-pentene, 1-hexene, 1-heptene, 4,4-dimethyl-1-pentene, 3-ethyl-1-pentene, 1-oetene, 1-nonene, 1-decene, 1-dodecene, 1-tetradecene, 1-hexadecene, 1-octadecene and 1-eicosene. Commercial examples of linear ethylene-based polymers that are interpolymers include ATTANEFM Ultra Low Density Linear Polyethylene Copolymer, DOWLEX™ Polyethylene Resins, and FLEXOMER™ Very Low Density Polyethylene, all available from The Dow Chemical Company.

In a further aspect, when used in reference to an ethylene homopolymer (that is, a high density ethylene homopolymer not containing any comonomer and thus no short chain branches), the terms “homogeneous ethylene polymer” or “homogeneous linear ethylene polymer” may be used to describe such a polymer.

In one aspect, the term “substantially linear ethylene polymer” as used refers to homogeneously branched ethylene polymers that have long chain branching. The term does not refer to heterogeneously or homogeneously branched ethylene polymers that have a linear polymer backbone. For substantially linear ethylene polymers, the long chain branches have about the same comonomer distribution as the polymer backbone, and the long chain branches can be as long as about the same length as the length of the polymer backbone to which they are attached. The polymer backbone of substantially linear ethylene polymers is substituted with about 0.01 long chain branches/1000 carbons to about 3 long chain branches/1000 carbons, more preferably from about 0.01 long chain branches/1000 carbons to about 1 long chain branches/1000 carbons, and especially from about 0.05 long chain branches/1000 carbons to about I long chain branches/1000 carbons.

Homogeneously branched ethylene polymers are homogeneous ethylene polymers that possess short chain branches and that are characterized by a relatively high composition distribution breadth index (CDBI). That is, the ethylene polymer has a CDBI greater than or equal to 50 percent, preferably greater than or equal to 70 percent, more preferably greater than or equal to 90 percent and essentially lack a measurable high density (crystalline) polymer fraction.

The CDBI is defined as the weight percent of the polymer molecules having a co-monomer content within 50 percent of the median total molar co-monomer content and represents a comparison of the co-monomer distribution in the polymer to the co-monomer distribution expected for a Bernoullian distribution. The CDBI of polyolefins can be conveniently calculated from data obtained from techniques known in the art, such as, for example, temperature rising elution fractionation (“TREF”) as described, for example, by Wild, et al., Journal of Polymer Science, Poly. Phys. Ed., Vol. 20, 441 (1982); L. D. Cady, “The Role of Comonomer Type and Distribution in LLDPE Product Performance,” SPE Regional Technical Conference, Quaker Square Hilton, Akron, OH, 107-119 (Oct. 1-2, 1985); or in U.S. Pat. No. 4,798,081 (Hazlitt, et al.) and U.S. Pat. No. 5,008,204 (Stehling). However, the TREF technique does not include purge quantities in CDBI calculations. More preferably, the co-monomer distribution of the polymer is determined using ¹³C NMR analysis in accordance with techniques described, for example, in U.S. Pat. No. 5,292,845 (Kawasaki, et al.) and by J. C. Randall in Rev. Macromol. Chem. Phys., C29, 201-317.

The terms “homogeneously branched linear ethylene polymer” and “homogeneously branched linear ethylene/a-olefin polymer” means that the olefin polymer has a homogeneous or narrow short branching distribution (that is, the polymer has a relatively high CDBI) but does not have long chain branching. That is, the linear ethylene-based polymer is a homogeneous ethylene polymer characterized by an absence of long chain branching. Such polymers can be made using polymerization processes (for example, as described by Elston) which provide a uniform short chain branching distribution (homogeneously branched). In the polymerization process described by Elston, soluble vanadium catalyst systems are used to make such polymers; however, others, such as Mitsui Petrochemical Industries and Exxon Chemical Company, have reportedly used so-called single site catalyst systems to make polymers having a homogeneous structure similar to polymer described by Elston. Further, Ewen, et al., and U.S. Pat. No. 5,218,071 (Tsutsui, et al.) disclose the use of metallocene catalysts for the preparation of homogeneously branched linear ethylene polymers. Homogeneously branched linear ethylene polymers are typically characterized as having a molecular weight distribution, M_{w}/Mₙ, of less than 3, preferably less than 2.8, more preferably less than 2.3.

In discussing linear ethylene-based polymers, the terms “homogeneously branched linear ethylene polymer” or “homogeneously branched linear ethylene/a-olefin polymer” do not refer to high pressure branched polyethylene which is known to those skilled in the art to have numerous long chain branches. In one aspect, the term “homogeneous linear ethylene polymer” generically refers to both linear ethylene homopolymers and to linear ethylene/α-olefin interpolymers. For example, a linear ethylene/α-olefin interpolymer possess short chain branching and the α-alefin is typically at least one C₃-C₂₀ α-alefin (for example, propylene, 1-butene, I -pentene, 4-methyl-1-pentene, 1-hexene, and 1-octene).

The presence of long chain branching can be determined in ethylene homopolymers by using ¹³C nuclear magnetic resonance (NMR) spectroscopy and is quantified using the method described by Randall (Rev. Macromol. Chem. Phys., C29, V. 2&3, 285-297). There are other known techniques useful for determining the presence of long chain branches in ethylene polymers, including ethylene/l-octene interpolymers. Two such exemplary methods are gel permeation chromatography coupled with a low angle laser light scattering detector (GPC-LALLS) and gel permeation chromatography coupled with a differential viscometer detector (GPC-DV). The use of these techniques for long chain branch detection and the underlying theories have been well documented in the literature. See, for example, Zimm, G. H. and Stockmayer, W. H., J. Chem. Phys., 17, 1301 (1949), and Rudin, A., Modern Methods of Polymer Characterization, John Wiley & Sons, New York (1991) 103-112.

In a further aspect, substantially linear ethylene polymers are homogeneously branched ethylene polymers and are disclosed in both U.S. Pat. Nos. 5,272,236 and 5,278,272 (both Lai, et al.). Homogeneously branched substantially linear ethylene polymers are available from The Dow Chemical Company of Midland, Michigan as AFFINITY™ polyolefin plastomers and ENGAGE™ polyolefin elastomers. Homogeneously branched substantially linear ethylene polymers can be prepared via the solution, slurry, or gas phase polymerization of ethylene and one or more optional α-alefin comonomers in the presence of a constrained geometry catalyst, such as the method disclosed in European Patent 0416815 (Stevens, et al.).

The terms “heterogeneous” and “heterogeneously branched” mean that the ethylene polymer can be characterized as a mixture of interpolymer molecules having various ethylene to comonomer molar ratios. Heterogeneously branched linear ethylene polymers are available from The Dow Chemical Company as DOWLEX™ linear low density polyethylene and as ATTANE™ ultra-low density polyethylene resins. Heterogeneously branched linear ethylene polymers can be prepared via the solution, slurry or gas phase polymerization of ethylene and one or more optional α-alefin comonomers in the presence of a Ziegler Natta catalyst, by processes such as are disclosed in U.S. Pat. No. 4,076,698 (Anderson, et al.). Heterogeneously branched ethylene polymers are typically characterized as having molecular weight distributions, Mw/Mn, from about 3.5 to about 4.1 and, as such, are distinct from substantially linear ethylene polymers and homogeneously branched linear ethylene polymers in regards to both compositional short chain branching distribution and molecular weight distribution.

Overall, the high crystallinity, ethylene-based polymers have a density of greater than or equal to about 0.89 g/cm3, preferably greater than or equal to about 0.91 g/cm3, and preferably less than or equal to about 0.97 g/cm3. Preferably, these polymers have a density from about 0.89 to about 0.97 g/cm3. All densities are determined by the Density method as described in the Test Methods section.

Highly Long Chain Branched Ethylene-Based Polymers

Highly long chain branched ethylene-based polymers, such as low density polyethylene (LDPE), can be made using a high-pressure process using free-radical chemistry to polymerize ethylene monomer. Typical polymer density is from about 0.91 to about 0.94 g/cm³. The low density polyethylene may have a melt index (I₂) from about 0.01 to about 150 g/10 minutes. Highly long chain branched ethylene-based polymers such as LDPE may also be referred to as “high pressure ethylene polymers”, meaning that the polymer is partly or entirely homopolymerized or copolymerized in autoclave or tubular reactors at pressures above 13,000 psig with the use of free-radical initiators, such as peroxides (see, for example, U.S. Pat. No. 4,599,392 (McKinney, et al.)). The process creates a polymer with significant branches, including long chain branches.

Highly long chain branched ethylene-based polymers are typically homopolymers of ethylene; however, the polymer may comprise units derived from one or more α-alefin copolymers as long as there is at least 50 mole percent polymerized ethylene monomer in the polymer.

Comonomers that may be used in forming highly branched ethylene-based polymer include, but are not limited to, α-alefin comonomers, typically having no more than 20 carbon atoms. For example, the α-alefin comonomers, for example, may have 3 to 10 carbon atoms; or in the alternative, the α-alefin comonomers, for example, may have 3 to 8 carbon atoms. Exemplary α-alefin comonomers include, but are not limited to, propylene, 1-butene, 1-pentene, 1-hexene, 1-heptene, 1-octene, 1-nonene, 1-decene, and 4-methyl-1-pentene. In the alternative, exemplary comonomers include, but are not limited to a, n-unsaturated C₃-C₈-carboxylic acids, in particular maleic acid, fumaric acid, itaconic acid, acrylic acid, methacrylic acid and crotonic acid derivates of the α, β-unsaturated C₃-C₈-carboxylic acids, for example unsaturated C₃-C₁₅-carboxylic acid esters, in particular ester of C₁-C₆-alkanols, or anhydrides, in particular methyl methacrylate, ethyl methacrylate, n-butyl methacrylate, ter-butyl methacrylate, methyl acrylate, ethyl acrylate n-butyl acrylate, 2-ethylhexyl acrylate, tert-butyl acrylate, methacrylic anhydride, maleic anhydride, and itaconic anhydride. In another alternative, the exemplary comonomers include, but are not limited to, vinyl carboxylates, for example vinyl acetate. In another alternative, exemplary comonomers include, but are not limited to, n-butyl acrylate, acrylic acid and methacrylic acid.

Process

The ethylene-based polymer may be produced before or separately from the reaction process with the highly branched ethylene-based polymer. In other disclosed processes, the ethylene-based polymer may be formed in situ and in the presence of highly branched ethylene-based polymer within a well-stirred reactor such as a tubular reactor or an autoclave reactor. The highly long chain branched ethylene-based polymer is formed in the presence of ethylene.

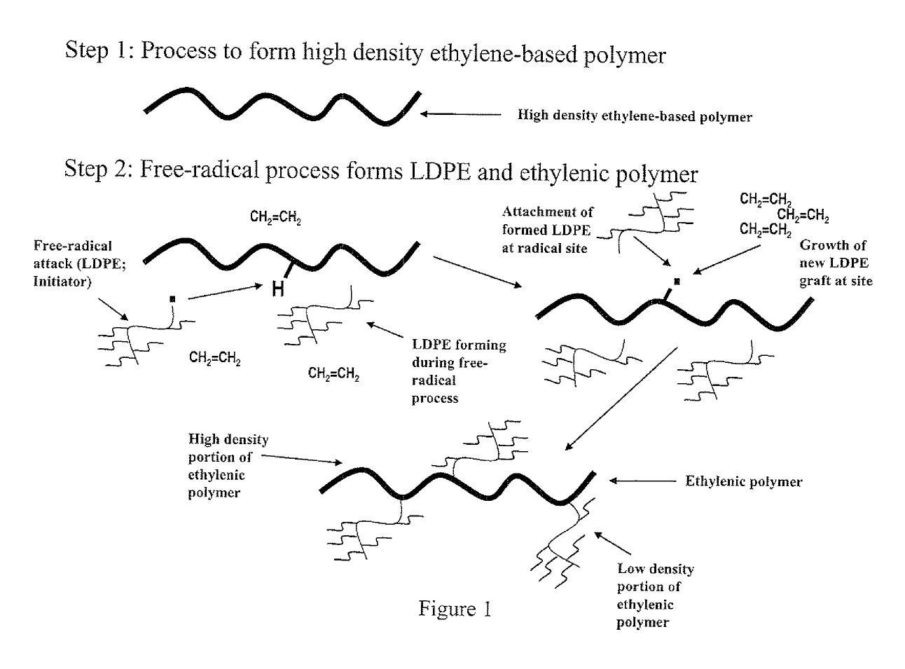

The ethylenie polymer is formed in the presence of ethylene. FIG. 1 give a general representation of free-radical ethylene polymerization to form a long chain branch from a radicalized linear ethylene-based polymer site of forming embodiment ethylenic polymers. Other embodiment processes for formation of the ethylene-based polymer, the substituent highly branched ethylene-based polymer, and their combination into the disclosed ethylenic polymer may exist.

In an embodiment process, the ethylene-based polymer is prepared externally to the reaction process used to form the embodiment ethylenic polymer, combined in a common reactor in the presence of ethylene under free-radical polymerization conditions, and subjected to process conditions and reactants to effect the formation of the embodiment ethylenic polymer.

In another embodiment process, the highly long chain branched ethylene-based polymer and the ethylene-based polymer are both prepared in different forward parts of the same process and are then combined together in a common downstream part of the process in the presence of ethylene under free-radical polymerization conditions. The ethylene-based polymer and the substituent highly long chain branched ethylene-based polymer are made in separate forward reaction areas or zones, such as separate autoclaves or an upstream part of a tubular reactor. The products from these forward reaction areas or zones are then transported to and combined in a downstream reaction area or zone in the presence of ethylene under free-radical polymerization conditions to facilitate the formation of an embodiment ethylenic polymer. In some processes, additional fresh ethylene is added to the process downstream of the forward reaction areas or zones to facilitate both the formation of and grafting of highly long chain branched ethylene-based polymers to the ethylene-based polymer and the reaction of ethylene monomer directly with the ethylene-based polymer to form the disclosed ethylenic polymer. In some other processes, at least one of the product streams from the forward reaction areas or zones is treated before reaching the downstream reaction area or zone to neutralize any residue or byproducts that may inhibit the downstream reactions.

In an embodiment in situ process, the ethylene-based polymer is created in a first or forward reaction area or zone, such as a first autoclave or an upstream part of a tubular reactor. The resultant product stream is then transported to a downstream reaction area or zone where there is a presence of ethylene at free-radical polymerization conditions. These conditions support both the formation of and grafting of highly long chain branched ethylene-based polymer to the ethylene-based polymer, thereby forming an embodiment ethylenic polymer. In some embodiment processes, free radical generating compounds are added to the downstream reaction area or zone to facilitate the grafting reaction. In some other embodiment processes, additional fresh ethylene is added to the process downstream of the forward reaction areas or zones to facilitate both the formation and grafting of highly long chain branched ethylene-based polymer to and the reaction of ethylene monomer with the ethylene-based polymer to form the disclosed ethylenic polymer. In some embodiment processes, the product stream from the forward reaction area or zone is treated before reaching the downstream reaction area or zone to neutralize any residue or byproducts from the previous reaction that may inhibit the highly branched ethylene-based polymer formation, the grafting of highly long chain branched ethylene-based polymer to the ethylene-based polymer, or the reaction of ethylene monomer with the ethylene-based polymer to form the disclosed ethylenic polymer.

For producing the ethylene-based polymer, a gas-phase polymerization process may be used. The gas-phase polymerization reaction typically occurs at low pressures with gaseous ethylene, hydrogen, a catalyst system, for example a titanium containing catalyst, and, optionally, one or more comonomers, continuously fed to a fluidized-bed reactor. Such a system typically operates at a pressure from about 300 to about 350 psi and a temperature from about 80 to about 100° C.

For producing the ethylene-based polymer, a solution-phase polymerization process may be used. Typically such a process occurs in a well-stirred reactor such as a loop reactor or a sphere reactor at temperature from about 150 to about 575° C., preferably from about 175 to about 205° C., and at pressures from about 30 to about 1000 psi, preferably from about 30 to about 750 psi. The residence time in such a process is from about 2 to about 20 minutes, preferably from about 10 to about 20 minutes. Ethylene, solvent, catalyst, and optionally one or more comonomers are fed continuously to the reactor. Exemplary catalysts in these embodiments include, but are not limited to, Ziegler-Natta, constrained geometry, and metallocene catalysts. Exemplary solvents include, but are not limited to, isoparaffins. For example, such solvents are commercially available under the name ISOPAR E (ExxonMobil Chemical Co., Houston, Tex.). The resultant mixture of ethylene-based polymer and solvent is then removed from the reactor and the polymer is isolated. Solvent is typically recovered via a solvent recovery unit, that is, heat exchangers and vapor liquid separator drum, and is recycled back into the polymerization system.

Any suitable method may be used for feeding the ethylene-based polymer into a reactor where it may be reacted with a highly long chain branched ethylene-based polymer. For example, in the cases where the ethylene-based polymer is produced using a gas phase process, the ethylene-based polymer may be dissolved in ethylene at a pressure above the highly long chain branched ethylene-based polymer reactor pressure, at a temperature at least high enough to dissolve the ethylene-based polymer and at concentration which does not lead to excessive viscosity before feeding to the highly long chain branched ethylene-based polymer reactor.

For producing the highly long chain branched ethylene-based polymer, a high pressure, free-radical initiated polymerization process is typically used. Two different high pressure free-radical initiated polymerization process types are known. In the first type, an agitated autoclave vessel having one or more reaction zones is used. The autoclave reactor normally has several injection points for initiator or monomer feeds, or both. In the second type, a jacketed tube is used as a reactor, which has one or more reaction zones. Suitable, but not limiting, reactor lengths may be from about 100 to about 3000 meters, preferably from about 1000 to about 2000 meters. The beginning of a reaction zone for either type of reactor is defined by the side injection of either initiator of the reaction, ethylene, telomer, comonomer(s) as well as any combination thereof A high pressure process can be carried out in autoclave or tubular reactors or in a combination of autoclave and tubular reactors, each comprising one or more reaction zones.

In embodiment processes, the catalyst or initiator is injected prior to the reaction zone where free radical polymerization is to be induced. In other embodiment processes, the ethylene-based polymer may be fed into the reaction system at the front of the reactor system and not formed within the system itself. Termination of catalyst activity may be achieved by a combination of high reactor temperatures for the free radical polymerization portion of the reaction or by feeding initiator into the reactor dissolved in a mixture of a polar solvent such as isopropanol, water, or conventional initiator solvents such as branched or unbranched alkanes.

Embodiment processes may be used for either the homopolymerization of ethylene in the presence of an ethylene-based polymer or copolymerization of ethylene with one or more other comonomers in the presence of an ethylene-based polymer, provided that these monomers are copolymerizable with ethylene under free-radical conditions in high pressure conditions to form highly long chain branched ethylene-based polymers.

Chain transfer agents or telogens (CTA) are typically used to control the melt index in a free-radical polymerization process. Chain transfer involves the termination of growing polymer chains, thus limiting the ultimate molecular weight of the polymer material. Chain transfer agents are typically hydrogen atom donors that will react with a growing polymer chain and stop the polymerization reaction of the chain. For high pressure free radical polymerizaton, these agents can be of many different types, such as hydrogen, saturated hydrocarbons, unsaturated hydrocarbons, aldehydes, ketones or alcohols. Typical CTAs that can be used include, but are not limited to, propylene, isobutane, n-butane, 1-butene, methyl ethyl ketone, propionaldehyde, ISOPAR (ExxonMobil Chemical Co.), and isopropanol. The amount of CTAs to use in the process is about 0.03 to about 10 weight percent of the total reaction mixture.

Free radical initiators that are generally used to produce ethylene-based polymers are oxygen, which is usable in tubular reactors in conventional amounts of between 0.0001 and 0.005 wt. % drawn to the weight of polymerizable monomer, and peroxides. Preferred initiators are t-butyl peroxy pivalate, di-t-butyl peroxide, t-butyl peroxy acetate and t-butyl peroxy-2-hexanoate or mixtures thereof. These organic peroxy initiators are used in conventional amounts of between 0.005 and 0.2 wt. % drawn to the weight of polymerizable monomers.

The peroxide initiator may be, for example, an organic peroxide. Exemplary organic peroxides include, but are not limited to, cyclic peroxides, diacyl peroxides, dialkyl peroxides, hydroperoxides, peroxycarbonates, peroxydicarbonates, peroxyesters, and peroxyketals.

In some embodiment processes, a peroxide initiator may initially be dissolved or diluted in a hydrocarbon solvent, and then a polar co-solvent added to the peroxide initiator/hydrocarbon solvent mixture prior to metering the free radical initiator system into the polymerization reactor. In another embodiment process, a peroxide initiator may be dissolved in the hydrocarbon solvent in the presence of a polar co-solvent.

The free-radical initiator used in the process may initiate the graft site on the linear ethylene-based polymer by extracting the extractable hydrogen from the linear ethylene-based polymer. Example free-radical initiators include those free radical initiators previously discussed, such as peroxides and azo compounds. In some other embodiment processes, ionizing radiation may also be used to free the extractable hydrogen and create the radicalized site on the linear ethylene-based polymer. Organic initiators are preferred means of extracting the extractable hydrogen, such as using dicumyl peroxide, di-tert-butyl peroxide, t-butyl perbenzoate, benzoyl peroxide, cumene hydroperoxide, t-butyl peroctoate, methyl ethyl ketone peroxide, 2,5-dimethyl-2,5-di(tert-butyl peroxy)hexane, lauryl peroxide, and tert-butyl peracetate, t-butyl α-cumyl peroxide, di-t-butyl peroxide, di-t-amyl peroxide, t-amyl peroxybenzoate, 1,1-bis(t-butylperoxy)-3,3,5-trimethylcyclohexane, α,α′-bis(t-butylperoxy)-1,3-diisopropylbenzene, α,α′-bis(t-butylpemxy)-1,4-diisopropylbenzene, 2,5-bis(t-butylperoxy)-2,5-dimethylhexane, and 2,5-bis(t-butylperoxy)-2,5-dimethyl-3-hexyne. A preferred azo compound is azobisisobutyl nitrite.

The embodiment ethylenic polymer may further be compounded. In some embodiment ethylenic polymer compositions, one or more antioxidants may further be compounded into the polymer and the compounded polymer pelletized. The compounded ethylenic polymer may contain any amount of one or more antioxidants. For example, the compounded ethylenic polymer may comprise from about 200 to about 600 parts of one or more phenolic antioxidants per one million parts of the polymer. In addition, the compounded ethylenic polymer may comprise from about 800 to about 1200 parts of a phosphite-based antioxidant per one million parts of polymer. The compounded disclosed ethylenic polymer may further comprise from about 300 to about 1250 parts of calcium stearate per one million parts of polymer.

### Photovoltaic Applications

Due to the lower density and modulus of the polyolefin copolymers used in the practice of this invention, these copolymers are typically cured or crosslinked at the time of contact or after, usually shortly after, the module has been constructed. Crosslinking is important to the performance of the copolymer in its function to protect the electronic device from the environment. Specifically, crosslinking enhances the thermal creep resistance of the copolymer and durability of the module in terms of heat, impact and solvent resistance. Crosslinking can be effected by any one of a number of different methods, e.g., by the use of thermally activated initiators, e.g., peroxides and azo compounds; photoinitiators, e.g., benzophenone; radiation techniques including sunlight, UV light, E-beam and x-ray; vinyl silane, e.g., vinyl tri-ethoxy or vinyl tri-methoxy silane; and moisture cure.

The free radical initiators used in the practice of this invention include any thermally activated compound that is relatively unstable and easily breaks into at least two radicals. Representative of this class of compounds are the peroxides, particularly the organic peroxides, and the azo initiators. Of the free radical initiators used as crosslinking agents, the dialkyl peroxides and diperoxyketal initiators are preferred. These compounds are described in the Encyclopedia of Chemical Technology, 3rd edition, Vol. 17, pp 27-90. (1982).

In the group of dialkyl peroxides, the preferred initiators are: dicumyl peroxide, di-t-butyl peroxide, t-butyl cumyl peroxide, 2,5-dimethyl-2,5-di(t-butylperoxy)-hexane, 2,5-dimethyl-2,5-di(t-amylperoxy)-hexane, 2,5-dimethyl-2,5-di(t-butylperoxy)hexyne-3, 2,5-dimethyl-2,5-di(t-amylperoxy)hexyne-3, a,a-di[(t-butylperoxy)-isopropyl]-benzene, di-t-amyl peroxide, 1,3,5-tri-[(t-butylperoxy)-isopropyl]benzene, 1,3-dimethyl-3-(t-butylperoxy)butanol, 1,3-dimethyl-3-(t-amylperoxy)butanol and mixtures of two or more of these initiators.

In the group of diperoxyketal initiators, the preferred initiators are: 1,1-di(t-butylperoxy)-3,3,5-trimethylcyclohexane, 1,1-di(t-butylperoxy)cyclohexane n-butyl, 4,4-di(t-amylperoxy)valerate, ethyl 3,3-di(t-butylperoxy)butyrate, 2,2-di(t-amylperoxy)propane, 3,6,6,9,9-pentamethyl-3-ethoxycarbonylmethyl-1,2,4,5-tetraoxacyclononane, n-butyl-4,4-bis(t-butylperoxy)-valerate, ethyl-3,3-di(t-amylperoxy)-butyrate and mixtures of two or more of these initiators.

Other peroxide initiators, e.g., 00-t-butyl-0-hydrogen-monoperoxysuccinate; 00-t-amyl-0-hydrogen-monoperoxysuccinate and/or azo initiators e.g., 2,2′-azobis-(2-acetoxypropane), may also be used to provide a crosslinked polymer matrix. Other suitable azo compounds include those described in U.S. Pat. No. 3,862,107 and 4,129,531. Mixtures of two or more free radical initiators may also be used together as the initiator within the scope of this invention. In addition, free radicals can form from shear energy, heat or radiation.

The amount of peroxide or azo initiator present in the crosslinkable compositions of this invention can vary widely, but the minimum amount is that sufficient to afford the desired range of crosslinking. The minimum amount of initiator is typically at least about 0.05, preferably at least about 0.1 and more preferably at least about 0.25, wt % based upon the weight of the polymer or polymers to be crosslinked. The maximum amount of initiator used in these compositions can vary widely, and it is typically determined by such factors as cost, efficiency and degree of desired crosslinking desired. The maximum amount is typically less than about 10, preferably less than about 5 and more preferably less than about 3, wt % based upon the weight of the polymer or polymers to be crosslinked.

Free radical crosslinking initiation via electromagnetic radiation, e.g., sunlight, ultraviolet (UV) light, infrared (IR) radiation, electron beam, beta-ray, gamma-ray, x-ray and neutron rays, may also be employed. Radiation is believed to affect crosslinking by generating polymer radicals, which may combine and crosslink. The Handbook of Polymer Foams and Technology, supra, at pp. 198-204, provides additional teachings. Elemental sulfur may be used as a crosslinking agent for diene containing polymers such as EPDM and polybutadiene. The amount of radiation used to cure the copolymer will vary with the chemical composition of the copolymer, the composition and amount of initiator, if any, the nature of the radiation, and the like, but a typical amount of UV light is at least about 0.05, more typically at about 0.1 and even more typically at least about 0.5, Joules/cm², and a typical amount of E-beam radiation is at least about 0.5, more typically at least about I and even more typically at least about 1.5, megarads.

If sunlight or UV light is used to effect cure or crosslinking, then typically and preferably one or more photoinitiators are employed. Such photoinitiators include organic carbonyl compounds such as such as benzophenone, benzanthrone, benzoin and alkyl ethers thereof, 2,2-diethoxyacetophenone, 2,2-dimethoxy, 2 phenylacetophenone, p-phenoxy dichloroacetophenone, 2-hydroxycyclohexylphenone, 2-hydroxyisopropylphenone, and 1-phenylpropanedione-2-(ethoxy carboxyl) oxime. These initiators are used in known manners and in known quantities, e.g., typically at least about 0.05, more typically at least about 0.1 and even more typically about 0.5, wt % based on the weight of the copolymer.

If moisture, i.e., water, is used to effect cure or crosslinking, then typically and preferably one or more hydrolysis/condensation catalysts are employed. Such catalysts include Lewis acids such as dibutyltin dilaurate, dioctyltin dilaurate, stannous octonoate, and hydrogen sulfonates such as sulfonic acid.

Free radical crosslinking coagents, i.e. promoters or co-initiators, include multifunctional vinyl monomers and polymers, triallyl cyanurate and trimethylolpropane trimethacrylate, divinyl benzene, acrylates and methacrylates of polyols, allyl alcohol derivatives, and low molecular weight polybutadiene. Sulfur crosslinking promoters include benzothiazyl disulfide, 2-mercaptobenzothiazole, copper dimethyldithiocarbamate, dipentamethylene thiuram tetrasulfide, tetrabutylthiuram disulfide, tetramethylthiuram disulfide and tetramethylthiuram monosulfide.

These coagents are used in known amounts and known ways. The minimum amount of coagent is typically at least about 0.05, preferably at least about 0.1 and more preferably at least about 0.5, wt % based upon the weight of the polymer or polymers to be crosslinked. The maximum amount of coagent used in these compositions can vary widely, and it is typically determined by such factors as cost, efficiency and degree of desired crosslinking desired. The maximum amount is typically less than about 10, preferably less than about 5 and more preferably less than about 3, wt % based upon the weight of the polymer or polymers to be crosslinked.

One difficulty in using thermally activated free radical initiators to promote crosslinking, i.e., curing, of thermoplastic materials is that they may initiate premature crosslinking, i.e., scorch, during compounding and/or processing prior to the actual phase in the overall process in which curing is desired. With conventional methods of compounding, such as milling, Banbury, or extrusion, scorch occurs when the time-temperature relationship results in a condition in which the free radical initiator undergoes thermal decomposition which, in turn, initiates a crosslinking reaction that can create gel particles in the mass of the compounded polymer. These gel particles can adversely impact the homogeneity of the final product. Moreover, excessive scorch can so reduce the plastic properties of the material that it cannot be efficiently processed with the likely possibility that the entire batch will be lost.

One method of minimizing scorch is the incorporation of scorch inhibitors into the compositions. For example, British patent 1,535,039 discloses the use of organic hydroperoxides as scorch inhibitors for peroxide-cured ethylene polymer compositions. U.S. Pat. No. 3,751,378 discloses the use of N-nitroso diphenylamine or N,N′-dinitroso-para-phenylamine as scorch retardants incorporated into a polyfunctional acrylate crosslinking monomer for providing long Mooney scorch times in various copolymer formulations. U.S. Pat. No. 3,202,648 discloses the use of nitrites such as isoamyl nitrite, tert-decyl nitrite and others as scorch inhibitors for polyethylene. U.S. Pat. No. 3,954,907 discloses the use of monomeric vinyl compounds as protection against scorch. U.S. Pat. No. 3,335,124 describes the use of aromatic amines, phenolic compounds, mercaptothiazole compounds, bis(N,N-disubstituted-thiocarbamoyl) sulfides, hydroquinones and dialkyldithiocarbamate compounds. U.S. Pat. No. 4,632,950 discloses the use of mixtures of two metal salts of disubstituted dithiocarbamic acid in which one metal salt is based on copper.

One commonly used scorch inhibitor for use in free radical, particularly peroxide, initiator-containing compositions is 4-hydroxy-2,2,6,6-tetramethylpiperidin-1-oxyl also known as nitroxyl 2, or NR 1, or 4-oxypiperidol, or tanol, or tempol, or tmpn, or probably most commonly, 4-hydroxy-TEMPO or even more simply, h-TEMPO. The addition of 4-hydroxy-TEMPO minimizes scorch by “quenching” free radical crosslinking of the crosslinkable polymer at melt processing temperatures.

The preferred amount of scorch inhibitor used in the compositions of this invention will vary with the amount and nature of the other components of the composition, particularly the free radical initiator, but typically the minimum amount of scorch inhibitor used in a system of polyolefin copolymer with 1.7 weight percent (wt %) peroxide is at least about 0.01, preferably at least about 0.05, more preferably at least about 0.1 and most preferably at least about 0.15, wt % based on the weight of the polymer. The maximum amount of scorch inhibitor can vary widely, and it is more a function of cost and efficiency than anything else. The typical maximum amount of scorch inhibitor used in a system of polyolefin copolymer with 1.7 wt % peroxide does not exceed about 2, preferably does not exceed about 1.5 and more preferably does not exceed about 1, wt % based on the weight of the copolymer.

Any silane that will effectively graft to and crosslink the polyolefin copolymer can be used in the practice of this invention. Suitable silanes include unsaturated silanes that comprise an ethylenically unsaturated hydrocarbyl group, such as a vinyl, allyl, isopropenyl, butenyl, cyclohexenyl or -(meth)acryloxy allyl group, and a hydrolyzable group, such as, for example, a hydrocarbyloxy, hydrocarbonyloxy, or hydrocarbylamino group. Examples of hydrolyzable groups include methoxy, ethoxy, formyloxy, acetoxy, proprionyloxy, and alkyl or arylamino groups. Preferred silanes are the unsaturated alkoxy silanes which can be grafted onto the polymer. These silanes and their method of preparation are more fully described in U.S. Pat. No. 5,266,627. Vinyl trimethoxy silane, vinyl triethoxy silane, -(meth)acryloxy propyl trimethoxy silane and mixtures of these silanes are the preferred silane crosslinkers for is use in this invention. If filler is present, then preferably the crosslinker includes vinyl triethoxy silane.

The amount of silane crosslinker used in the practice of this invention can vary widely depending upon the nature of the polyolefin copolymer, the silane, the processing conditions, the grafting efficiency, the ultimate application, and similar factors, but typically at least 0.5, preferably at least 0.7, parts per hundred resin wt % is used based on the weight of the copolymer. Considerations of convenience and economy are usually the two principal limitations on the maximum amount of silane crosslinker used in the practice of this invention, and typically the maximum amount of silane crosslinker does not exceed 5, preferably it does not exceed 2, wt % based on the weight of the copolymer.

The silane crosslinker is grafted to the polyolefin copolymer by any conventional method, typically in the presence of a free radical initiator e.g. peroxides and azo compounds, or by ionizing radiation, etc. Organic initiators are preferred, such as any of those described above, e.g., the peroxide and azo initiators. The amount of initiator can vary, but it is typically present in the amounts described above for the crosslinking of the polyolefin copolymer.

While any conventional method can be used to graft the silane crosslinker to the polyolefin copolymer, one preferred method is blending the two with the initiator in the first stage of a reactor extruder, such as a Buss kneader. The grafting conditions can vary, but the melt temperatures are typically between 160 and 260° C., preferably between 190 and 230° C., depending upon the residence time and the half life of the initiator.

In another embodiment of the invention, the polymeric material further comprises a graft polymer to enhance the adhesion to one or more glass cover sheets to the extent that these sheets are components of the electronic device module. While the graft polymer can be any graft polymer compatible with the polyolefin copolymer of the polymeric material and which does not significantly compromise the performance of the polyolefin copolymer as a component of the module, typically the graft polymer is a graft polyolefin polymer and more typically, a graft polyolefin copolymer that is of the same composition as the polyolefin copolymer of the polymeric material. This graft additive is typically made in situ simply by subjecting the polyolefin copolymer to grafting reagents and grafting conditions such that at least a portion of the polyolefin copolymer is grafted with the grafting material.

Any unsaturated organic compound containing at least one ethylenic unsaturation (e.g., at least one double bond), at least one carbonyl group (—C═O), and that will graft to a polymer, particularly a polyolefin polymer and more particularly to a polyolefin copolymer, can be used as the grafting material in this embodiment of the invention. Representative of compounds that contain at least one carbonyl group are the carboxylic acids, anhydrides, esters and their salts, both metallic and nonmetallic. Preferably, the organic compound contains ethylenic unsaturation conjugated with a carbonyl group. Representative compounds include maleic, fumaric, acrylic, methacrylic, itaconic, crotonic, α-methyl crotonic, and cinnamic acid and their anhydride, ester and salt derivatives, if any. Maleic anhydride is the preferred unsaturated organic compound containing at least one ethylenic unsaturation and at least one carbonyl group.

The unsaturated organic compound content of the graft polymer is at least about 0.01 wt %, and preferably at least about 0.05 wt %, based on the combined weight of the polymer and the organic compound. The maximum amount of unsaturated organic compound content can vary to convenience, but typically it does not exceed about 10 wt %, preferably it does not exceed about 5 wt %, and more preferably it does not exceed about 2 wt %.

The unsaturated organic compound can be grafted to the polymer by any known technique, such as those taught in U.S. Pat. Nos. 3,236,917 and 5,194,509. For example, in the '917 patent the polymer is introduced into a two-roll mixer and mixed at a temperature of 60° C. The unsaturated organic compound is then added along with a free radical initiator, such as, for example, benzoyl peroxide, and the components are mixed at 30° C. until the grafting is completed. In the '509 patent, the procedure is similar except that the reaction temperature is higher, e.g., 210 to 300° C., and a free radical initiator is not used or is used at a reduced concentration.

An alternative and preferred method of grafting is taught in U.S. Pat. No. 4,950,541 by using a twin-screw devolatilizing extruder as the mixing apparatus. The polymer and unsaturated organic compound are mixed and reacted within the extruder at temperatures at which the reactants are molten and in the presence of a free radical initiator. Preferably, the unsaturated organic compound is injected into a zone maintained under pressure within the extruder.

The polymeric materials of this invention can comprise other additives as well. For example, such other additives include UV-stabilizers and processing stabilizers such as trivalent phosphorus compounds. The UV-stabilizers are useful in lowering the wavelength of electromagnetic radiation that can be absorbed by a PV module (e.g., to less than 360 nm), and include hindered phenols such as Cyasorb UV2908 and hindered amines such as Cyasorb UV 3529, Hostavin N30, Univil 4050, Univin 5050, Chimassorb UV 119, Chimassorb 944 LD, Tinuvin 622 LD and the like. The phosphorus compounds include phosphonites (PEPQ) and phosphites (Weston 399, TNPP, P-168 and Doverphos 9228). The amount of UV-stabilizer is typically from about 0.1 to 0.8%, and preferably from about 0.2 to 0.5%. The amount of processing stabilizer is typically from about 0.02 to 0.5%, and preferably from about 0.05 to 0.15%.

Still other additives include, but are not limited to, antioxidants (e.g., hindered phenolics (e.g., Irganox® 1010 made by Ciba Geigy Corp.)), cling additives, e.g., PIB, anti-blocks, anti-slips, anti-stats, pigments and fillers (clear if transparency is important to the application). In-process additives, e.g. calcium stearate, water, etc., may also be used. These and other potential additives are used in the manner and amount as is commonly known in the art.

The polymeric materials of this invention are used to construct electronic device modules in the same manner and using the same amounts as the encapsulant materials known in the art, e.g., such as those taught in USP 6,586,271, US Patent Application Publication US2001/0045229 A1, WO 99/05206 and WO 99/04971. These materials can be used as “skins” for the electronic device, i.e., applied to one or both face surfaces of the device, or as an encapsulant in which the device is totally enclosed within the material. Typically, the polymeric material is applied to the device by one or more lamination techniques in which a layer of film formed from the polymeric material is applied first to one face surface of the device, and then to the other face surface of the device. In an alternative embodiment, the polymeric material can be extruded in molten form onto the device and allowed to congeal on the device. The polymeric materials of this invention exhibit good adhesion for the face surfaces of the device.

In one embodiment, the electronic device module comprises (i) at least one electronic device, typically a plurality of such devices arrayed in a linear or planar pattern, (ii) at least one glass cover sheet, typically a glass cover sheet over both face surfaces of the device, and (iii) at least one polymeric material. The polymeric material is typically disposed between the glass cover sheet and the device, and the polymeric material exhibits good adhesion to both the device and the sheet. If the device requires access to specific forms of electromagnetic radiation, e.g., sunlight, infrared, ultra-violet, etc., then the polymeric material exhibits good, typically excellent, transparency for that radiation, e.g., transmission rates in excess of 90, preferably in excess of 95 and even more preferably in excess of 97, percent as measured by UV-vis spectroscopy (measuring absorbance in the wavelength range of about 250-1200 nanometers). An alternative measure of transparency is the internal haze method of ASTM D-1003-00. If transparency is not a requirement for operation of the electronic device, then the polymeric material can contain opaque filler and/or pigment.

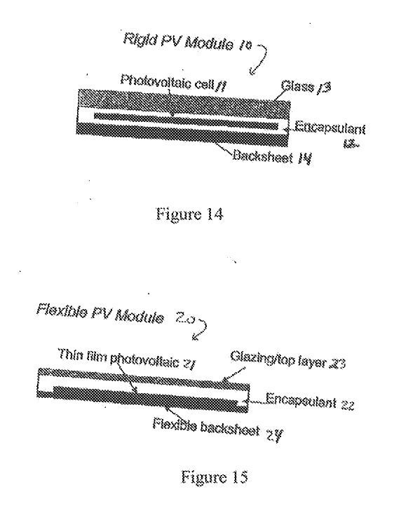

In FIG. 14, rigid PV module 10 comprises photovoltaic cell 11 surrounded or encapsulated by transparent protective layer or encapsulant 12 comprising a polyolefin copolymer used in the practice of this invention. Glass cover sheet 13 covers a front surface of the portion of the transparent protective layer disposed over PV cell 11. Backskin or back sheet 14, e.g., a second glass cover sheet or another substrate of any kind, supports a rear surface of the portion of transparent protective layer 12 disposed on a rear surface of PV cell 11. Backskin layer 14 need not be transparent if the surface of the PV cell to which it is opposed is not reactive to sunlight. In this embodiment, protective layer 12 encapsulates PV cell 11. The thicknesses of these layers, both in an absolute context and relative to one another, are not critical to this invention and as such, can vary widely depending upon the overall design and purpose of the module. Typical thicknesses for protective layer 12 are in the range of about 0.125 to about 2 millimeters (mm), and for the glass cover sheet and backskin layers in the range of about 0.125 to about 1.25 mm. The thickness of the electronic device can also vary widely.

In FIG. 15, flexible PV module 20 comprises thin film photovoltaic 21 over-lain by transparent protective layer or encapsulant 22 comprising a polyolefin copolymer used in the practice of this invention. Glazing/top layer 23 covers a front surface of the portion of the transparent protective layer disposed over thin film PV 21. Flexible backskin or back sheet 24, e.g., a second protective layer or another flexible substrate of any kind, supports the bottom surface of thin film PV 21. Backskin layer 24 need not be transparent if the surface of the thin film cell which it is supporting is not reactive to sunlight. In this embodiment, protective layer 21 does not encapsulate thin film PV 21. The overall thickness of a typical rigid or flexible PV cell module will typically be in the range of about 5 to about 50 mm.

The modules described in FIGS. 14 and 15 can be constructed by any number of different methods, typically a film or sheet co-extrusion method such as blown-film, modified blown-film, calendaring and casting. In one method and referring to FIG. 14, protective layer 14 is formed by first extruding a polyolefin copolymer over and onto the top surface of the PV cell and either simultaneously with or subsequent to the extrusion of this first extrusion, extruding the same, or different, polyolefin copolymer over and onto the back surface of the cell. Once the protective film is attached the PV cell, the glass cover sheet and backskin layer can be attached in any convenient manner, e.g., extrusion, lamination, etc., to the protective layer, with or without an adhesive. Either or both external surfaces, i.e., the surfaces opposite the surfaces in contact with the PV cell, of the protective layer can be embossed or otherwise treated to enhance adhesion to the glass and backskin layers. The module of FIG. 15 can be constructed in a similar manner, except that the backskin layer is attached to the PV cell directly, with or without an adhesive, either prior or subsequent to the attachment of the protective layer to the PV cell.

### Test Methods

### Density

Samples that are measured for density are prepared according to ASTM D 1928. Measurements are made within one hour of sample pressing using ASTM D792, Method B.

For some highly long chain branched ethylene-based polymers, density is calculated (“calculated density”) in grams per cubic centimeter based upon a relationship with the heat of fusion (H_{f}) in Joules per gram of the sample. The heat of fusion of the polymer sample is determined using the DSC Crystallinity method described infra.

To establish a relationship between density and heat of fusion for highly branched ethylene based polymers, thirty commercially available LDPE resins (designated “Commercially Available Resins” or “CAR”) are tested for density, melt index (H, heat of fusion, peak melting temperature, g′, gpcBR, and LCBf using the Density, Melt Index, DSC Crystallinity, Gel Permeation Chromatography, g′ by 3D-GPC, and gpcBR Branching Index by 3D-GPC methods, all described infra. The Commercially Available Resins have the properties listed in Table 1.

TABLE 1
Properties for several Commercially Available Resins.

| | | Melt | | | | | | |
|---|---|---|---|---|---|---|---|---|
| Commercially | | Index (I₂) | Heat of | | | | | |
| Available | Density | (g/10 | Fusion | Peak | gpcBR | | | |
| Resins | (g/cm³) | min) | (J/g) | Tₘ (° C.) | Whole | g′ avg | MH | LCBf |
| CAR1 | 0.920 | 0.15 | 147.2 | 110.9 | 1.26 | 0.56 | 0.48 | 2.05 |
| CAR2 | 0.922 | 2.5 | 151.1 | 111.4 | 0.89 | 0.62 | 0.49 | 2.03 |
| CAR3 | 0.919 | 0.39 | 146.8 | 110.4 | 1.19 | 0.56 | 0.50 | 2.39 |
| CAR4 | 0.922 | 0.80 | 155.0 | 112.5 | 0.78 | 0.61 | 0.50 | 1.99 |
| CAR5 | 0.916 | 28 | 139.3 | 106.6 | 1.27 | 0.59 | 0.44 | 3.59 |
| CAR6 | 0.917 | 6.4 | 141.5 | 107.8 | 1.48 | 0.56 | 0.45 | 3.24 |
| CAR7 | 0.924 | 1.8 | 155.1 | 112.2 | 0.77 | 0.63 | 0.51 | 1.84 |
| CAR8 | 0.926 | 5.6 | 157.9 | 113.4 | 0.57 | 0.67 | 0.54 | 1.64 |
| CAR9 | 0.923 | 0.26 | 151.4 | 110.3 | 1.13 | 0.58 | 0.51 | 2.06 |
| CAR10 | 0.924 | 0.22 | 151.2 | 111.4 | 1.03 | 0.58 | 0.50 | 1.96 |
| CAR11 | 0.924 | 0.81 | 154.1 | 112.3 | 0.95 | 0.58 | 0.50 | 2.48 |
| CAR12 | 0.926 | 5.9 | 158.0 | 113.1 | 0.70 | 0.66 | 0.50 | 1.90 |
| CAR13 | 0.924 | 2.0 | 155.2 | 111.8 | 0.84 | 0.61 | 0.49 | 2.03 |
| CAR14 | 0.923 | 4.1 | 157.3 | 111.6 | 1.26 | 0.60 | 0.38 | 2.32 |
| CAR15 | 0.922 | 33 | 153.5 | 111.8 | 0.46 | 0.69 | 0.27 | 1.95 |
| CAR16 | 0.922 | 4.1 | 151.0 | 109.3 | 1.89 | 0.57 | 0.34 | 2.61 |
| CAR17 | 0.918 | 0.46 | 141.2 | 107.4 | 3.09 | 0.46 | 0.39 | 3.33 |
| CAR18 | 0.921 | 2.1 | 145.9 | 110.2 | 0.85 | 0.60 | 0.41 | 2.11 |
| CAR19 | 0.918 | 8.2 | 143.2 | 106.4 | 2.27 | 0.54 | 0.33 | 3.20 |
| CAR20 | 0.922 | 0.67 | 148.7 | 110.4 | 0.68 | 0.62 | 0.42 | 1.59 |
| CAR21 | 0.924 | 0.79 | 154.2 | 111.8 | 0.74 | 0.60 | 0.48 | 1.96 |
| CAR22 | 0.922 | 0.25 | 150.0 | 110.5 | 0.92 | 0.57 | 0.47 | 1.92 |
| CAR23 | 0.924 | 3.4 | 153.6 | 111.3 | 0.65 | 0.63 | 0.48 | 1.94 |
| CAR24 | 0.921 | 4.6 | 148.2 | 106.9 | 1.49 | 0.58 | 0.36 | 2.54 |
| CAR25 | 0.923 | 20 | 150.9 | 108.9 | NM | NM | NM | 2.21 |
| CAR26 | 0.925 | 1.8 | 157.5 | 112.4 | 0.82 | 0.64 | 0.50 | 1.86 |
| CAR27 | 0.923 | 0.81 | 153.7 | 111.5 | 0.87 | 0.62 | 0.50 | 1.94 |
| CAR28 | 0.919 | 6.8 | 145.1 | 105.7 | 1.72 | 0.57 | 0.36 | 2.75 |
| CAR29 | 0.931 | 3.6 | 167.3 | 115.6 | NM | NM | NM | NM |
| CAR30 | 0.931 | 2.3 | 169.3 | 115.8 | NM | NM | NM | NM |

Note that “NM” means not measured.

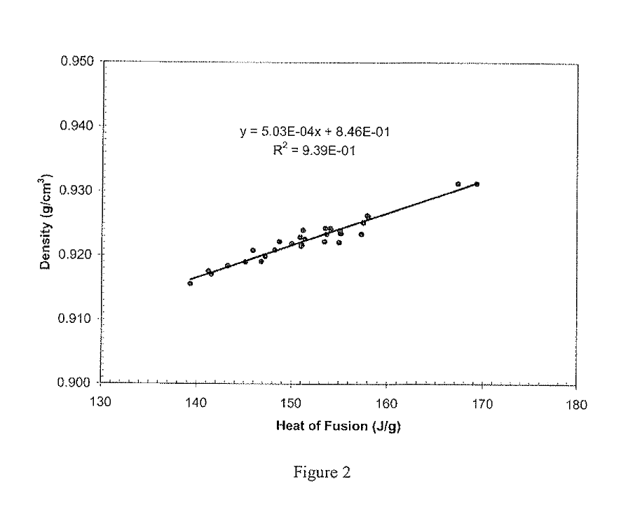

A graph showing the relationship between density and heat of fusion (H_{f}) for the Commercially Available Resins is shown in FIG. 2. R² given in FIG. 2 is the square of a correlation coefficient between the observed and modeled data values. Based upon a linear regression, a calculated density, in grams per cubic centimeter, of commercially available highly long chain branched ethylene based polymers can be determined from the heat of fusion, in Joules per gram, using Equation 1:

Calculated density=5.03E−04*(H_{f})+8.46E−01 (Eq. 1).

Melt Index

Melt index, or I₂, is measured in accordance with ASTM D 1238, Condition 190° C./2.16 kg, and is reported in grams eluted per 10 minutes. I₁₀ is measured in accordance with ASTM D 1238, Condition 190° C./10 kg, and is reported in grams eluted per 10 minutes.

Brookfield Viscosity

Melt viscosity is determined using a Brookfield Laboratories (Middleboro, Mass.) DVII+Viscometer and disposable aluminum sample chambers. The spindle used is a SC-31 hot-melt spindle suitable for measuring viscosities from about 10 to about 100,000 centipoises. Other spindles may be used to obtain viscosities if the viscosity of the polymer is out of this range or in order to obtain the recommended torque ranges as described in this procedure. The sample is poured into the sample chamber, inserted into a Brookfield Thermosel, and locked into place. The sample chamber has a notch on the bottom that fits the bottom of the Brookfield Thermosel to ensure that the chamber is not allowed to turn when the spindle is inserted and spinning. The sample is heated to the required temperature (177° C.), until the melted sample is about 1 inch (approximately 8 grams of resin) below the top of the sample chamber. The viscometer apparatus is lowered and the spindle submerged into the sample chamber. Lowering is continued until brackets on the viscometer align on the Thermosel. The viscometer is turned on, and set to operate at a shear rate which leads to a torque reading from about 30 to about 60 percent. Readings are taken every minute for about 15 minutes or until the values stabilize, at which point, a final reading is recorded.

DSC Crystallinity

Differential Scanning calorimetry (DSC) can be used to measure the melting and crystallization behavior of a polymer over a wide range of temperature. For example, the TA Instruments Q1000 DSC, equipped with an RCS (refrigerated cooling system) and an autosampler is used to perform this analysis. During testing, a nitrogen purge gas flow of 50 ml/min is used. Each sample is melt pressed into a thin film at about 175° C.; the melted sample is then air-cooled to room temperature (˜25° C.). A 3-10 mg, 6 mm diameter specimen is extracted from the cooled polymer, weighed, placed in a light aluminum pan (Ca 50 mg), and crimped shut. Analysis is then performed to determine its thermal properties.

The thermal behavior of the sample is determined by ramping the sample temperature up and down to create a heat flow versus temperature profile. First, the sample is rapidly heated to 180° C. and held isothermal for 3 minutes in order to remove its thermal history. Next, the sample is cooled to −40° C. at a 10° C./minute cooling rate and held isothermal at −40° C. for 3 minutes. The sample is then heated to 150° C. (this is the “second heat” ramp) at a 10° C./minute heating rate. The cooling and second heating curves are recorded. The cool curve is analyzed by setting baseline endpoints from the beginning of crystallization to −20° C. The heat curve is analyzed by setting baseline endpoints from −20° C. to the end of melt. The values determined are peak melting temperature (Tₘ), peak crystallization temperature (T_{c}), heat of fusion (H_{f}) (in Joules per gram), and the calculated % crystallinity for polyethylene samples using Equation 2:

% Crystallinity=((H_{f})/(292 J/g)×100 (Eq. 2).

The heat of fusion (H_{f}) and the peak melting temperature are reported from the second heat curve. Peak crystallization temperature is determined from the cooling curve.

Gel Permeation Chromatography (GPC)

The GPC system consists of a Waters (Milford, Mass.) 150° C. high temperature chromatograph (other suitable high temperatures GPC instruments include Polymer Laboratories (Shropshire, UK) Model 210 and Model 220) equipped with an on-board differential refractometer (RI). Additional detectors can include an IR4 infra-red detector from Polymer ChAR (Valencia, Spain), Precision Detectors (Amherst, Mass.) 2-angle laser light scattering detector Model 2040, and a Viscotek (Houston, Tex.) 150R 4-capillary solution viscometer. A GPC with the last two independent detectors and at least one of the first detectors is sometimes referred to as “3D-GPC”, while the term “GPC” alone generally refers to conventional GPC. Depending on the sample, either the 15-degree angle or the 90-degree angle of the light scattering detector is used for calculation purposes. Data collection is performed using Viscotek TriSEC software, Version 3, and a 4-channel Viscotek Data Manager DM400. The system is also equipped with an on-line solvent degassing device from Polymer Laboratories (Shropshire, UK). Suitable high temperature GPC columns can be used such as four 30 cm long Shodex HT803 13 micron columns or four 30 cm Polymer Labs columns of 20-micron mixed-pore-size packing (MixA LS, Polymer Labs). The sample carousel compartment is operated at 140° C. and the column compartment is operated at 150° C. The samples are prepared at a concentration of 0.1 grams of polymer in 50 milliliters of solvent. The chromatographic solvent and the sample preparation solvent contain 200 ppm of butylated hydroxytoluene (BHT). Both solvents are sparged with nitrogen. The polyethylene samples are gently stirred at 160° C. for four hours. The injection volume is 200 microliters. The flow rate through the GPC is set at 1 ml/minute.

The GPC column set is calibrated before running the Examples by running twenty-one narrow molecular weight distribution polystyrene standards. The molecular weight

(MW) of the standards ranges from 580 to 8,400,000 grams per mole, and the standards are contained in 6 “cocktail” mixtures. Each standard mixture has at least a decade of separation between individual molecular weights. The standard mixtures are purchased from Polymer Laboratories (Shropshire, UK). The polystyrene standards are prepared at 0.025 g in 50 mL of solvent for molecular weights equal to or greater than 1,000,000 grams per mole and 0.05 g in 50 ml of solvent for molecular weights less than 1,000,000 grams per mole. The polystyrene standards were dissolved at 80° C. with gentle agitation for 30 minutes. The narrow standards mixtures are run first and in order of decreasing highest molecular weight component to minimize degradation. The polystyrene standard peak molecular weights are converted to polyethylene M_{w} using the Mark-Houwink K and a (sometimes referred to as a) values mentioned later for polystyrene and polyethylene. See the Examples section for a demonstration of this procedure.

With 3D-GPC absolute weight average molecular weight (“M_{w, Abs}”) and intrinsic viscosity are also obtained independently from suitable narrow polyethylene standards using the same conditions mentioned previously. These narrow linear polyethylene standards may be obtained from Polymer Laboratories (Shropshire, UK; Part No.'s PL2650-0101 and PL2650-0102).

The systematic approach for the determination of multi-detector offsets is performed in a manner consistent with that published by Balke, Mourey, et al. (Mourey and Balke, Chromatography Polym., Chapter 12, (1992)) (Balke, Thitiratsakul, Lew, Cheung, Mourey, Chromatography Polym., Chapter 13, (1992)), optimizing triple detector log (M_{W} and intrinsic viscosity) results from Dow 1683 broad polystyrene (American Polymer Standards Corp.; Mentor, Ohio) or its equivalent to the narrow standard column calibration results from the narrow polystyrene standards calibration curve. The molecular weight data, accounting for detector volume off-set determination, are obtained in a manner consistent with that published by Zimm (Zimm, B. H., J. Chem. Phys., 16, 1099 (1948)) and Kratochvil (Kratochvil, P., Classical Light Scattering from Polymer Solutions, Elsevier, Oxford, N.Y. (1987)). The overall injected concentration used in the determination of the molecular weight is obtained from the mass detector area and the mass detector constant derived from a suitable linear polyethylene homopolymer, or one of the polyethylene standards. The calculated molecular weights are obtained using a light scattering constant derived fi⁻om one or more of the polyethylene standards mentioned and a refractive index concentration coefficient, dn/dc, of 0.104. Generally, the mass detector response and the light scattering constant should be determined from a linear standard with a molecular weight in excess of about 50,000 daltons. The viscometer calibration can be accomplished using the methods described by the manufacturer or alternatively by using the published values of suitable linear standards such as Standard Reference Materials (SRM) 1475a, 1482a, 1483, or 1484a. The chromatographic concentrations are assumed low enough to eliminate addressing 2^{nd} viral coefficient effects (concentration effects on molecular weight).

Analytical Temperature Rising Elution Fractionation (ATREF)

ATREF analysis is conducted according to the methods described in U.S. Pat. No. 4,798,081 (Hazlitt, et al.) and Wild, L.; Ryle, T. R.; Knobeloch, D. C.; Peat, I. R.; “Determination of Branching Distributions in Polyethylene and Ethylene Copolymers”, J. Polym. Sci., 20, 441-55 (1982). The configurations and equipment are described in Hazlitt, L. G., “Determination of Short-chain Branching Distributions of Ethylene Copolymers by Automated Temperature Rising Elution Fractionation (Auto-ATREF)”, Journal of Applied Polymer Science: Appl. Polym. Symp., 45, 25-39 (1990). The polymer sample is dissolved in TCB (0.2% to 0.5% by weight) at 120° C. to 140° C., loaded on the column at an equivalent temperature, and allowed to crystallize in a column containing an inert support (stainless steel shot, glass beads, or a combination thereof) by slowly reducing the temperature to 20° C. at a cooling rate of 0.1° C./minute. The column is connected to an infrared detector (and, optionally, to a LALLS detector and viscometer) commercially available as described in the Gel Permeation Chromatography Method section. An ATREF chromatogram curve is then generated by eluting the crystallized polymer sample from the column while increasing the temperature (1° C./minute) of the column and eluting solvent from 20 to 120° C. at a rate of 1.0° C./minute.

Fast Temperature Rising Elution Fractionation (F-TREF)

The fast-TREF is performed with a Crystex instrument by Polymer ChAR (Valencia, Spain) in orthodichlorobenzene (ODCB) with IR-4 infrared detector in compositional mode (Polymer ChAR, Spain) and light scattering (LS) detector (Precision Detector Inc., Amherst, Mass.).

In F-TREF, 120 mg of the sample is added into a Crystex reactor vessel with 40 ml of ODCB held at 160° C. for 60 minutes with mechanical stirring to achieve sample dissolution. The sample is loaded onto TREF column. The sample solution is then cooled down in two stages: (1) from 160° C. to 100° C. at 40° C./minute, and (2) the polymer crystallization process started from 100° C. to 30° C. at 0.4° C./minute. Next, the sample solution is held isothermally at 30° C. for 30 minutes. The temperature-rising elution process starts from 30° C. to 160° C. at 1.5° C./minute with flow rate of 0.6 ml/minute. The sample loading volume is 0.8 ml. Sample molecular weight (M_{W}) is calculated as the ratio of the 15° or 90° LS signal over the signal from measuring sensor of IR-4 detector. The LS-MW calibration constant is obtained by using polyethylene national bureau of standards SRM 1484a. The elution temperature is reported as the actual oven temperature. The tubing delay volume between the TREF and detector is accounted for in the reported TREF elution temperature.

Preparative Temperature Rising Elution Fractionation (P-TREF)

The temperature rising elution fractionation method (TREF) used to preparatively fractionate the polymers (P-TREF) is derived from Wilde, L.; Ryle, T. R.; Knobeloch, D. C.; Peat, I. R.; “Determination of Branching Distributions in Polyethylene and Ethylene Copolymers”, J. Polym. Sci., 20, 441-455 (1982), including column dimensions, solvent, flow and temperature program. An infrared (IR) absorbance detector is used to monitor the elution of the polymer from the column. Separate temperature programmed liquid baths—one for column loading and one for column elution—are also used.

Samples are prepared by dissolution in trichlorobenzene (TCB) containing approximately 0.5% 2,6-di-tert-butyl-4-methylphenol at 160° C. with a magnetic stir bar providing agitation. Sample load is approximately 150 mg per column. After loading at 125° C., the column and sample are cooled to 25° C. over approximately 72 hours. The cooled sample and column are then transferred to the second temperature programmable bath and equilibrated at 25° C. with a 4 ml/minute constant flow of TCB. A linear temperature program is initiated to raise the temperature approximately 0.33° C./minute, achieving a maximum temperature of 102° C. in approximately 4 hours.

Fractions are collected manually by placing a collection bottle at the outlet of the IR detector. Based upon earlier ATREF analysis, the first fraction is collected from 56 to 60° C. Subsequent small fractions, called subfractions, are collected every 4° C. up to 92° C., and then every 2° C. up to 102° C. Subtractions are referred to by the midpoint elution temperature at which the subfraction is collected.

Subfractions are often aggregated into larger fractions by ranges of midpoint temperature to perform testing. For the purposes of testing embodiment ethylenic polymers, subfractions with midpoint temperatures in the range of 97 to 101° C. are combined together to give a fraction called “Fraction A”. Subfractions with midpoint temperatures in the range of 90 to 95° C. are combined together to give a fraction called “Fraction B”. Subtractions with midpoint temperatures in the range of 82 to 86° C. are combined together to give a fraction called “Fraction C”. Subfractions with midpoint temperatures in the range of 62 to 78° C. are combined together to give a fraction called “Fraction D”. Fractions may be further combined into larger fractions for testing purposes.

A weight-average elution temperature is determined for each Fraction based upon the average of the elution temperature range for each subtraction and the weight of the subtraction versus the total weight of the sample. Weight average temperature as determined by Equation 3 is defined as:

$${T}_{w} = \frac{{\sum }_{T}^{ } T ( f ) * A ( f )}{{\sum }_{T}^{ } A ( f )} , \qquad ( Eq . 3 )$$

where T(f) is the mid-point temperature of a narrow slice or segment and A(f) is the area of the segment, proportional to the amount of polymer, in the segment.

Data are stored digitally and processed using an EXCEL (Microsoft Corp.; Redmond, Wash.) spreadsheet. The TREF plot, peak maximum temperatures, fraction weight percentages, and fraction weight average temperatures were calculated with the spreadsheet program.

Post P-TREF Polymer Fraction Preparation

Fractions A, B, C, and D are prepared for subsequent analysis by removal of trichlorobenzene (TCB). This is a multi-step process in which one part TCB solution is combined with three parts methanol. The precipitated polymer for each fraction is filtered onto fluoropolymer membranes, washed with methanol, and air dried. The polymer-containing filters are then placed in individual vials with enough xylene to cover the filter. The vials are heated to 135° C., at which point the polymer either dissolves in the xylene or is lifted from the filter as plates or flakes. The vials are cooled, the filters are removed, and the xylene is evaporated under a flowing nitrogen atmosphere at room temperature. The vials are then placed in a vacuum oven, the pressure reduced to −28 inches Hg, and the temperature raised to 80° C. for two hours to remove residual xylene. The four Fractions are analyzed using IR spectroscopy and gel permeation chromatography to obtain a number average molecular weight. For IR analysis, Fractions may have to he combined into larger fractions to obtain a high enough signal to noise in the IR spectra.

Methyls Per 1000 Carbons Determination on P-TREF Fractions

The analysis follows Method B in ASTM D-2238 except for slight deviation in the procedure to account for smaller-than-standard sample sizes, as described in this procedure.

In the ASTM procedure polyethylene films approximately 0.25 mm thick are scanned by infrared and analyzed. The procedure described is modified to permit similar testing using smaller amounts of material generated by the P-TREF separation.

For each of the Fractions, a piece of polymer is pressed between aluminum foil in a heated hydraulic press to create a film approximately 4 mm in diameter and 0.02 mm thick. The film is then placed on a NaCl disc 13 mm in diameter and 2 mm thick and scanned by infrared using an IR microscope. The FTIR spectrometer is a Thermo Nicolet Nexus 470 with a Continuum microscope equipped with a liquid nitrogen cooled MCT detector. One hundred twenty eight scans are collected at 2 wavenumber resolution using 1 level of 0 filling.

The methyls are measured using the 1378 cm⁻¹ peak. The calibration used is the same calibration derived by using ASTM D-2238. The FTIR is equipped with Therino Nicolet Omnic software.

The uncorrected methyls per 1000 carbons, X, are corrected for chain ends using their corresponding number average molecular weight, Mₙ, to obtain corrected methyls per thousand, Y, as shown in Equation 4:

Y=X−21,000/Mₙ (Eq. 4).

The value of 21,000 is used to allow for the lack of reliable signal to obtain unsaturation levels in the sub-fractions. In general, though, these corrections are small (<0.4 methyls per 1000 carbons).

g′ by 3D-GPC

The index (g′) for the sample polymer is determined by first calibrating the light scattering, viscosity, and concentration detectors described in the Gel Permeation Chromatography method supra with SRM 1475a homopolymer polyethylene (or an equivalent reference). The light scattering and viscometer detector offsets are determined relative to the concentration detector as described in the calibration. Baselines are subtracted from the light scattering, viscometer, and concentration chromatograms and integration windows are then set making certain to integrate all of the low molecular weight retention volume range in the light scattering and viscometer chromatograms that indicate the presence of detectable polymer from the refractive index chromatogram. A linear homopolymer polyethylene is used to establish a Mark-Houwink (MH) linear reference line by injecting a broad molecular weight polyethylene reference such as SRM1475a standard, calculating the data file, and recording the intrinsic viscosity (IV) and molecular weight (M_{W}), each derived from the light scattering and viscosity detectors respectively and the concentration as determined from the RI detector mass constant for each chromatographic slice. For the analysis of samples the procedure for each chromatographic slice is repeated to obtain a sample Mark-Houwink line. Note that for some samples the lower molecular weights, the intrinsic viscosity and the molecular weight data may need to be extrapolated such that the measured molecular weight and intrinsic viscosity asymptotically approach a linear homopolymer GPC calibration curve. To this end, many highly-branched ethylene-based polymer samples require that the linear reference line be shifted slightly to account for the contribution of short chain branching before proceeding with the long chain branching index (g′) calculation.

A g-prime (gᵢ′) is calculated for each branched sample chromatographic slice (i) and measuring molecular weight (Mᵢ) according to Equation 5:

gᵢ′ =(IV_{Sample,i}/IV_{linear reference,j}) (Eq. 5),

where the calculation utilizes the IV_{linear reference,j} at equivalent molecular weight, Mⱼ, in the linear reference sample. In other words, the sample IV slice (i) and reference IV slice (j) have the same molecular weight (Mᵢ=Mⱼ). For simplicity, the IV_{linear reference,j} slices are calculated from a fifth-order polynomial fit of the reference Mark-Houwink Plot. The IV ratio, or gᵢ′, is only obtained at molecular weights greater than 3,500 because of signal-to-noise limitations in the light scattering data. The number of branches along the sample polymer (Bₙ) at each data slice (i) can be determined by using Equation 6, assuming a viscosity shielding epsilon factor of 0.75:

$${[ \frac{I {V}_{Sample , i}}{I {V}_{linear \_ reference , j}} ]}_{{M}_{i = j}}^{1.33} = {[ {( 1 + \frac{{B}_{n , i}}{7} )}^{1 / 2} + \frac{4}{9} \frac{{B}_{n , i}}{π} ]}^{- 1 / 2} . \qquad ( Eq . 6 )$$

Finally, the average LCBf quantity per 1000 carbons in the polymer across all of the slices (i) can be determined using Equation 7:

$$LCBf = \frac{{\sum }_{M = 3500}^{i} ( \frac{{B}_{n , i}}{{M}_{i} \text{/} 14000} {c}_{i} )}{\sum {c}_{i}} . \qquad ( Eq . 7 )$$

gpcBR Branching Index by 3D-GPC

In the 3D-GPC configuration the polyethylene and polystyrene standards can be used to measure the Mark-Houwink constants, K and a, independently for each of the two polymer types, polystyrene and polyethylene. These can be used to refine the Williams and Ward polyethylene equivalent molecular weights in application of the following methods.

The gpcBR branching index is determined by first calibrating the light scattering, viscosity, and concentration detectors as described previously. Baselines are then subtracted from the light scattering, viscometer, and concentration chromatograms. Integration windows are then set to ensure integration of all of the low molecular weight retention volume range in the light scattering and viscometer chromatograms that indicate the presence of detectable polymer from the refractive index chromatogram. Linear polyethylene standards are then used to establish polyethylene and polystyrene Mark-Houwink constants as described previously. Upon obtaining the constants, the two values are used to construct two linear reference conventional calibrations (“cc”) for polyethylene molecular weight and polyethylene intrinsic viscosity as a function of elution volume, as shown in Equations 8 and 9:

$$\begin{matrix}{M}_{PE} = {( \frac{{K}_{PS}}{{K}_{PE}} )}^{1 / {α}_{PE} + 1} \cdot {M}_{PS}^{{α}_{PS} + 1 / {α}_{PE} + 1} , and & ( Eq . 8 ) \\ {[ η ]}_{PE} = {K}_{PS} \cdot {M}_{PS}^{α + 1} / {M}_{PE} . & ( Eq . 9 )\end{matrix}$$

The gpcBR branching index is a robust method for the characterization of long chain branching. See Yau, Wallace W., “Examples of Using 3D-GPC—TREF for Polyolefin Characterization”, Macromol. Symp., 2007, 257, 29-45. The index avoids the slice-by-slice 3D-GPC calculations traditionally used in the determination of g′ values and branching frequency calculations in favor of whole polymer detector areas and area dot products. From 3D-GPC data, one can obtain the sample bulk M_{w} by the light scattering (LS) detector using the peak area method. The method avoids the slice-by-slice ratio of light scattering detector signal over the concentration detector signal as required in the g′ determination.

$${M}_{W} = {\sum }_{i}^{ } {w}_{i} {M}_{i} = {\sum }_{i}^{ } ( \frac{{C}_{i}}{{\sum }_{i}^{ } {C}_{i}} ) {M}_{i} = \frac{{\sum }_{i}^{ } {C}_{i} {M}_{i}}{{\sum }_{i}^{ } {C}_{i}} = \frac{{\sum }_{i}^{ } L {S}_{i}}{{\sum }_{i}^{ } {C}_{i}} = \frac{L S Area}{Conc . Area} . \qquad ( Eq . 10 )$$

The area calculation in Equation 10 offers more precision because as an overall sample area it is much less sensitive to variation caused by detector noise and GPC settings on baseline and integration limits. More importantly, the peak area calculation is not affected by the detector volume offsets. Similarly, the high-precision sample intrinsic viscosity (IV) is obtained by the area method shown in Equation 11:

$$I V = [ η ] = {\sum }_{i}^{ } {w}_{i} I {V}_{i} = {\sum }_{i}^{ } ( \frac{{C}_{i}}{{\sum }_{i}^{ } {C}_{i}} ) I {V}_{i} = \frac{{\sum }_{i}^{ } {C}_{i} I {V}_{i}}{{\sum }_{i}^{ } {C}_{i}} = \frac{{\sum }_{i}^{ } {DP}_{i}}{{\sum }_{i}^{ } {C}_{i}} = \frac{DP Area}{Conc . Area} , \qquad ( Eq . 11 )$$

where DPᵢ stands for the differential pressure signal monitored directly from the online viscometer.

To determine the gpcBR branching index, the light scattering elution area for the sample polymer is used to determine the molecular weight of the sample. The viscosity detector elution area for the sample polymer is used to determine the intrinsic viscosity (IV or [η]) of the sample.

Initially, the molecular weight and intrinsic viscosity for a linear polyethylene standard sample, such as SRM1475a or an equivalent, are determined using the conventional calibrations for both molecular weight and intrinsic viscosity as a function of elution volume, per Equations 12 and 13:

$$\begin{matrix}{Mw}_{CC} = {\sum }_{i}^{ } ( \frac{{C}_{i}}{{\sum }_{i}^{ } {C}_{i}} ) {M}_{i} = {\sum }_{i}^{ } {w}_{i} {M}_{i} , and & ( Eq . 12 ) \\ {[ η ]}_{CC} = {\sum }_{i}^{ } ( \frac{{C}_{i}}{{\sum }_{i}^{ } {C}_{i}} ) I {V}_{i} = {\sum }_{i}^{ } {w}_{i} I {V}_{i} . & ( Eq . 13 )\end{matrix}$$

Equation 14 is used to determine the gpcBR branching index:

$$gpcBR = [ ( \frac{{[ η ]}_{CC}}{[ η ]} ) \cdot {( \frac{{M}_{W}}{{M}_{W , CC}} )}^{{α}_{PE}} - 1 ] , \qquad ( Eq . 14 )$$

where [η] is the measured intrinsic viscosity, [η]_{cc} is the intrinsic viscosity from the conventional calibration, M_{w} is the measured weight average molecular weight, and M_{w,cc} is the weight average molecular weight of the conventional calibration. The Mw by light scattering (LS) using Equation (10) is commonly referred to as the absolute Mw; while the Mw,cc from Equation (12) using the conventional GPC molecular weight calibration curve is often referred to as polymer chain Mw. All statistical values with the “cc” subscript are determined using their respective elution volumes, the corresponding conventional calibration as previously described, and the concentration (Cᵢ) derived from the mass detector response. The non-subscripted values are measured values based on the mass detector, LALLS, and viscometer areas. The value of K_{PE} is adjusted iteratively until the linear reference sample has a gpcBR measured value of zero. For example, the final values for α and Log K for the determination of gpcBR in this particular case are 0.725 and −3.355, respectively, for polyethylene, and 0.722 and −3.993 for polystyrene, respectively.

Once the K and a values have been determined, the procedure is repeated using the branched samples. The branched samples are analyzed using the final Mark-Houwink constants as the best “cc” calibration values and applying Equations 10-14.

The interpretation of gpcBR is straight forward. For linear polymers, gpcBR calculated from Equation 14 will be close to zero since the values measured by LS and viscometry will be close to the conventional calibration standard. For branched polymers, gpcBR will be higher than zero, especially with high levels of LCB, because the measured polymer M_{w} will be higher than the calculated and the calculated IV_{cc} will be higher than the measured polymer IV. In fact, the gpcBR value represents the fractional IV change due the molecular size contraction effect as the result of polymer branching. A gpcBR value of 0.5 or 2.0 would mean a molecular size contraction effect of IV at the level of 50% and 200%, respectively, versus a linear polymer molecule of equivalent weight.

For these particular Examples, the advantage of using gpcBR in comparison to the g′ index and branching frequency calculations is due to the higher precision of gpcBR. All of the parameters used in the gpcBR index determination are obtained with good precision and are not detrimentally affected by the low 3D-GPC detector response at high molecular weight from the concentration detector. Errors in detector volume alignment also do not affect the precision of the gpcBR index determination. In other particular cases, other methods for determining M_{w} moments may be preferable to the aforementioned technique.

Nuclear Magnetic Resonance (¹³C NMR)

Samples involving LDPE and the inventive examples are prepared by adding approximately 3 g of a 50/50 mixture of tetrachloroethane-d₂/orthodichlorobenzene containing 0.025 M Cr(AcAc)₃ to a 0.25 g polymer sample in a 10 mm NMR tube. Oxygen is removed from the sample by placing the open tubes in a nitrogen environment for at least 45 minutes. The samples are then dissolved and homogenized by heating the tube and its contents to 150° C. using a heating block and heat gun. Each dissolved sample is visually inspected to ensure homogeneity. Samples are thoroughly mixed immediately prior to analysis and were not allowed to cool before insertion into the heated NMR sample holders.

The ethylene-based polymer samples are prepared by adding approximately 3 g of a 50/50 mixture of tetrachloroethane-d₂/orthodichlorobenzene containing 0.025 M Cr(AcAc)₃ to 0.4 g polymer sample in a 10 mm NMR tube. Oxygen is removed from the sample by placing the open tubes in a nitrogen environment for at least 45 minutes. The samples are then dissolved and homogenized by heating the tube and its contents to 150° C. using a heating block and heat gun. Each dissolved sample is visually inspected to ensure homogeneity. Samples are thoroughly mixed immediately prior to analysis and are not allowed to cool before insertion into the heated NMR sample holders.

All data are collected using a Bruker 400 MHz spectrometer. The data is acquired using a 6 second pulse repetition delay, 90-degree flip angles, and inverse gated decoupling with a sample temperature of 125° C. All measurements are made on non-spinning samples in locked mode. Samples are allowed to thermally equilibrate for 15 minutes prior to data acquisition. The ¹³C NMR chemical shifts were internally referenced to the EEE triad at 30.0 ppm.

C13 NMR Comonomer Content

It is well known to use NMR spectroscopic methods for determining polymer composition. ASTM D 5017-96, J. C. Randall et al., in “NMR and Macromolecules” ACS Symposium series 247, J. C. Randall, Ed., Am. Chem. Soc., Washington, D.C., 1984, Ch. 9, and J. C. Randall in “Polymer Sequence Determination”, Academic Press, New York (1977) provide general methods of polymer analysis by NMR spectroscopy.

Cross-Fractionation by TREF (xTREF)

The cross-fractionation by TREF (xTREF) provides a separation by both molecular weight and crystallinity using ATREF and GPC. Nakano and Goto, J. Appl. Polym. Sci., 24, 4217-31 (1981), described the first development of an automatic cross fractionation instrument. The typical xTREF process involves the slow crystallization of a polymer sample onto an ATREF column (composed of glass beads and steel shot). After the ATREF step of crystallization the polymer is sequentially eluted in predetermined temperature ranges from the ATREF column and the separated polymer fractions are measured by GPC. The combination of the elution temperature profile and the individual GPC profiles allow for a 3-dimensional representation of a more complete polymer structure (weight distribution of polymer as function of molecular weight and crystallinity). Since the elution temperature is a good indicator for the presence of short chain branching, the method provides a fairly complete structural description of the polymer.

A detailed description of the design and operation of the cross-fractionation instrument can be found in PCT Publication No. WO 2006/081116 (Gillespie, et al.). FIG. 12 shows a schematic for the xTREF instrument 500. This instrument has a combination of at least one ATREF oven 600 and a GPC 700. In this method, a Waters GPC 150 is used. The xTREF instrument 500, through a series of valve movements, operates by (1) injecting solutions into a sample loop and then to the ATREF column, (2) crystallizing the polymer by cooling the ATREF oven/column, and (3) eluting the fractions in step-wise temperature increments into the GPC. Heated transfer lines 505, kept at approximately 150° C., are used for effluent flow between various components of the xTREF instrument 500. Five independent valve systems (GPC 700 2-way/6-port valve 750 and 2-way/3-port valve 760; ATREF oven 600 valves 650, 660, and 670) control the flow path of the sample.

The refractive index (RI) GPC detector 720 is quite sensitive to solvent flow and temperature. Fluctuations in the solvent pressure during crystallization and elution can lead to elution artifacts during the TREF elution. An external infrared (IR) detector 710, the IR4, supplied by Polymer ChAR (Valencia, Spain) is added as the primary concentration detector (RI detector 720) to alleviate this concern. Other detectors (not shown) are the LALLS and viscometer configured as described in the Gel Permeation Chromatography method, provided infra in the Testing Methods section. In FIG. 12, a 2-way/6-port valve 750 and a 2-way/3-port valve 760 (Valco; Houston, Tex.) are placed in the Waters 150° C. heated column compartment 705.

Each ATREF oven 600 (Gaumer Corporation, Houston, Tex.) uses a forced flow gas (nitrogen) design and are well insulated. Each ATREF column 610 is constructed of 316 SS 0.125″ OD by 0.105″ (3.18 millimeter) ID precision bore tubing. The tubing is cut to 19.5″ (495.3 millimeters) length and filled with a 60/40 (v/v) mix of stainless steel 0.028″ (0.7 millimeter) diameter cut wire shot and 30-40 mesh spherical technical quality glass. The stainless steel cut wire shot is from Pellets, Inc. (North Tonawanda, N.Y.). The glass spheres are from Potters Industries (Brownwood, Tex.). The interstitial volume was approximately 1.00 ml. Parker fitted low internal volume column end fittings (Part number 2-1 Z2HCZ-4-SS) are placed on each tube end and the tubing is wrapped into a 1.5″ (38.1 millimeters) coil. Since TCB has a very high heat capacity at a standard flowrate of 1.0 ml/minute, the ATREF column 610 (which has an interstitial volume of around 1 ml) may be heated or quenched without the pre-equilibration coil 605. It should be noted that the pre-equilibration coil 605 has a large volume (>12 milliliters) and, therefore, is only inline during the ATREF elution cycle (and not the ATREF loading cycle). The nitrogen to the ATREF oven 600 passed through a thermostatically controlled chiller (Airdyne; Houston, Tex.) with a 100 psig nitrogen supply capable of discharging 100 set/minute of 5 to 8° C. nitrogen. The chilled nitrogen is piped to each analytical oven for improved low temperature control purposes.

The polyethylene samples are prepared in 2-4 mg/ml TCB depending upon the distribution, density, and the desired number of fractions to be collected. The samples preparation is similar to that of conventional GPC.

The system flow rate is controlled at 1 ml/minute for both the GPC elution and the ATREF elution using the GPC pump 740 and GPC sample injector 745. The GPC separation is accomplished through four 10 μm “Mixed B” linear mixed bed GPC columns 730 supplied by Polymer Laboratories (UK). The GPC heated column compartment 705 is operated at 145° C. to prevent precipitation when eluting from the ATREF column 610. Sample injection amount is 500 μl. The ATREF oven 600 conditions are: temperature is from about 30 to about 110° C.; crystallization rate of about 0.123° C/minute during a 10.75 hour period; an elution rate of 0.123° C./minute during a 10.75 hour period; and 14 P-TREF fractions.

The GPC 700 is calibrated in the same way as for conventional GPC except that there is “dead volume” contained in the cross-fractionation system due to the ATREF column 610. Providing a constant volume offset to the collected GPC data from a given ATREF column 610 is easily implemented using the fixed time interval that is used while the ATREF column 620 is being loaded from the GPC sample injector 745 and converting that (through the flow rate) to an elution volume equivalent. The offset is necessary because during the operation of the instrument, the GPC start time is determined by the valve at the exit end of the ATREF column and not the GPC injector system. The presence of the ATREF column 610 also causes some small reduction in apparent GPC column 730 efficiency. Careful construction of the ATREF columns 610 will minimize its effect on GPC column 730 performance.

During a typical analysis, 14 individual ATREF fractions are measured by GPC. Each ATREF fraction represents approximately a 5-7° C.-temperature “slice”. The molecular weight distribution (MWD) of each slice is calculated from the integrated GPC chromatograms. A plot of the GPC MWDs as a function of temperature (resulting in a 3D surface plot) depicts the overall molecular weight and crystallinity distribution. In order to create a smoother 3D surface, the 14 fractions are interpolated to expand the surface plot to include 40 individual GPC chromatograms as part of the calculation process. The area of the individual GPC chromatograms correspond to the amount eluted from the ATREF fraction (across the 5-7° C.-temperature slice). The individual heights of GPC chromatograms (Z-axis on the 3D plot) correspond to the polymer weight fraction thus giving a representation of the proportion of polymer present at that level of molecular weight and crystallinity.

### EXAMPLES

Preparation of Ethylene-Based Polymers

A continuous solution polymerization is carried out in a computer-controlled well mixed reactor to form three ethylene-based polyethylene polymers. The solvent is a purified mixed alkanes solvent called ISOPAR E (ExxonMobil Chemical Co., Houston, Tex.). A feed of ethylene, hydrogen, and polymerization catalyst are fed into a 39 gallon (0.15 cubic meters) reactor. See Table 2 for the amounts of feed and reactor conditions for the formation of each of the three ethylene-based polyethylene polymers, designated Polymer (P) 1-3. “SCCM” in Table 2 is standard cubic centimeters per minute gas flow. The catalyst for all three of the ethylene-based polyethylene polymers is a titanium-based constrained geometry catalyst (CGC) with the composition Titanium, [N-(1,1-dimethylethyl)-1,1-dimethyl-1-[(1,2,3,3 a,7a-η)-3-(1-pyrrolidinyl)-1H-inden-1-yl]silanaminato(2-)-κN][(1,2,3,4-η)-1,3-pentadiene]. The cocatalyst is a modified methylalumoxane (MMAO). The CGC activator is a blend of amines, bis(hydrogenated tallow alkyl)methyl, and tetrakis(pentafluorophenyl)borate(1-). The reactor is run liquid-full at approximately 525 psig.

The process of polymerization is similar to the procedure detailed in Examples 1-4 and FIG. 1 of U.S. Pat. No. 5,272,236 (Lai, et al.) and Example 1 of U.S. Pat. No. 5,278,272 (Lai, et al.), except that a comonomer is not used in forming LP 1-3. Because no comonomer is used, LP 1-3 are ethylene homopolymers. Conversion is measured as percent ethylene conversion in the reactor. Efficiency is measured as the weight of the polymer in kilograms produced by grams of titanium in the catalyst.

After emptying the reactor, additives (1300 ppm IRGAFOS 168, 200 ppm IRGANOX 1010, 250 ppm IRGANOX 1076, 1250 ppm calcium stearate) are injected into each of the three ethylene-based polyethylene polymer post-reactor solutions. Each post-reactor solution is then heated in preparation for a two-stage devolatization. The solvent and unreacted monomers are removed from the post-reactor solution during the devolatization process. The resultant polymer melt is pumped to a die for underwater pellet cutting.

Selected properties for LPI-3 are provided in Table 3. LP1-3 are presented with density, melt index (I₂), I₁₀, and Brookfield viscosity determined using the Density, Melt Index, and Brookfield Viscosity methods, all described infra. “NM” means not measured.

TABLE 2
Feed amounts and reactor conditions for creating ethylene-based polymers LP1-3.

| | | | | | | | | | | | Poly- | | | |
|---|---|---|---|---|---|---|---|---|---|---|---|---|---|---|
| | | | | | | | Acti- | | Co- | Co- | meriz- | | | |
| | C₂H₄ | Solvent | | | | Catalyst | vator | Activator | catalyst | catalyst | ation | Con- | | |
| Polymer | Feed | Feed | H₂ | T | Catalyst | Flow | Conc. | Flow | Conc. | Flow | Rate | version | Solids | Effi- |
| Samples | (kg/hr) | (kg/hr) | (sccm) | (° C.) | (ppm) | (kg/hr) | (ppm) | (kg/hr) | (ppm) | (kg/hr) | (kg/hr) | (%) | % | ciency |
| LP1 | 178 | 1,261 | 19,067 | 160 | 84 | 0.5897 | 3,462 | 0.5012 | 311 | 0.7160 | 160 | 85.3 | 11.1 | 3,239 |
| LP2 | 144 | 1,021 | 25,581 | 157 | 441 | 0.6020 | 5,572 | 1.783 | 699 | 0.8553 | 139 | 90.4 | 11.9 | 522 |
| LP3 | 177 | 1,260 | 8,998 | 150 | 84 | 0.3777 | 3,462 | 0.3187 | 291 | 0.4917 | 157 | 84.1 | 10.9 | 4,956 |

TABLE 3
Selected properties for ethylene-based polymers LP1-3.

| | | | | | Brookfield |
|---|---|---|---|---|---|
| Polymer | Density | | | | Viscosity (cP) |
| Samples | (g/cm³) | I₂ | I₁₀ | I₁₀/I₂ | 177° C. |
| LP1 | 0.965 | 62 | 387 | 6.2 | NM |
| LP2 | 0.967 | NM | NM | NM | 10,818 |
| LP3 | 0.958 | 4.9 | 29 | 5.8 | NM |

Preparation of Example Ethylenic Polymers 1 and 2

### Example 1

Two grams of Polymer 2 (LP2) are added to a 100 ml autoclave reactor. After closing the reactor, the agitator is turned on at 1000 rpm (revolutions per minute). The reactor is deoxygenated by pulling vacuum on the system and pressurizing with nitrogen. This is repeated three times. The reactor is then pressurized with ethylene up to 2000 bar while at ambient temperatures and then vented off. This is repeated three times. On the final ethylene vent of the reactor, the pressure is dropped only to a pressure of about 100 bar, where the reactor heating cycle is initiated. Upon achieving an internal temperature of −220° C., the reactor is then pressurized with ethylene to about 1600 bar and held at 220° C. for at least 30 minutes. The estimated amount of ethylene in the reactor is approximately 46.96 grams. Ethylene is then used to sweep 3.0 ml of a mixture of 0.5648 mmol/ml propionaldehyde and 0.01116 mmol/ml tert-butyl peroxyacetate initiator in n-heptane into the reactor. An increase in pressure (to ˜2000 bar) in conjunction with the addition of initiator causes the ethylene monomer to free-radical polymerize. The polymerization leads to a temperature increase to 274° C. After allowing the reactor to continue to mix for 15 minutes, the reactor is depressurized, purged, and opened. A total of 4.9 grams of resultant ethylenic polymer, designated Example 1, is physically recovered from the reactor (some additional product polymer is unrecoverable due to the reactor bottom exit plugging). Based upon the conversion value of ethylene in the reactor, the ethylenic polymer of Example 1 comprises up to 40 weight percent ethylene-based polyethylene LP2 and the balance is highly long chain branched ethylene-based polymer generated by free-radical polymerization.

### Comparative Example 1

Free-radical polymerization of ethylene under the same process conditions as Example 1 without the addition of an ethylene-based polymer yields 4.9 grams of a highly long chain branched ethylene-based polymer designated as Comparative Example 1 (CE1). A temperature increase to 285° C. occurs during the reaction.

### Example 2

Two grams of Polymer 1 (LP1) are added to a 100 ml autoclave reactor. After closing the reactor, the agitator is turned on at 1000 rpm. The reactor is deoxygenated by pulling vacuum on the system and pressurizing with nitrogen. This is repeated three times. The reactor is then pressurized with ethylene up to 2000 bar while at ambient temperatures and then vented off. This is repeated three times. On the final ethylene vent of the reactor, the pressure is dropped only to a pressure of about 100 bar, where the reactor heating cycle is initiated. Upon achieving an internal temperature of ˜220° C., the reactor is then pressurized with ethylene to about 1600 bar and held at 220° C. for at least 30 minutes. At this point the estimated amount of ethylene in the reactor is approximately 46.96 grams. Ethylene is then used to sweep 3.0 ml of a mixture of 0.5648 mmol/ml propionaldehyde and 0.01116 mmol/ml tert-butyl peroxyacetate initiator in n-heptane into the reactor. The increase in pressure (to ˜2000 bar) in conjunction with the addition of initiator causes the ethylene to free-radical polymerize. The polymerization leads to a temperature increase to 267° C. After allowing the reactor to continue to mix for 15 minutes, the reactor is depressurized, purged, and opened. A total of 7.4 grams of resultant ethylenic polymer, designated Example 2, is physically recovered from the reactor (some additional product polymer is unrecoverable due to the reactor bottom exit plugging). Based upon the conversion value of ethylene in the reactor, ethylenic polymer of Example 2 comprises approximately 27 weight percent ethylene-based polyethylene LP 1 and the balance is highly long chain branched ethylene-based polymer generated by free-radical polymerization.

Characterization of Example Ethylenic Polymers 1 and 2

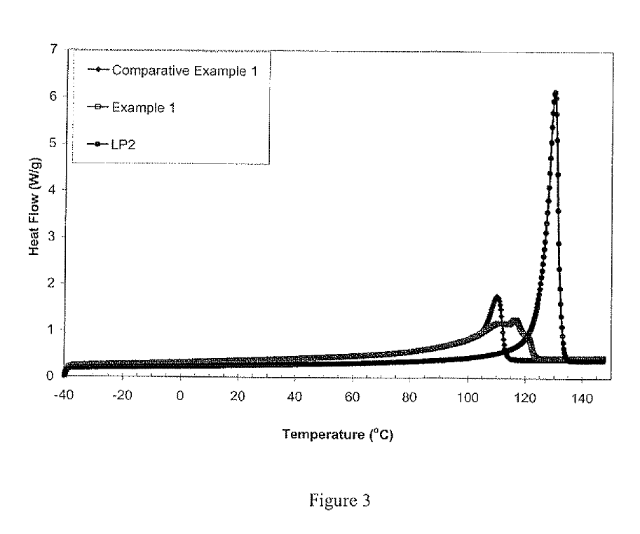

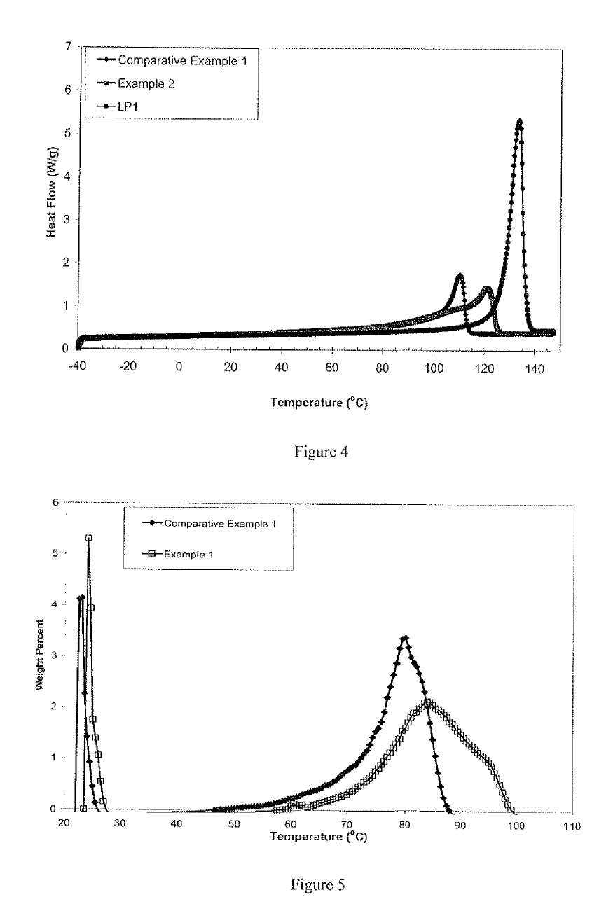

Both ethylenic polymers Examples 1 and 2, highly long chain branched ethylene-based polymer Comparative Example 1, and both ethylene-based polymers LP1 and LP2 are tested using the DSC Crystallinity method, provided infra in the Testing Methods section. The calculated density for the Comparative Example polymer are from the use of the Density method, provided infra in the Testing Methods section. Results of the testing are provided in Table 4 and FIGS. 3 and 4.

TABLE 4
Results of DSC Crystallinity testing for Examples 1 and 2, Comparative Example 1, and LP1 and LP2.

| | | | High | | | | |
|---|---|---|---|---|---|---|---|
| | | | Melting | | | | |
| | Heat of | | Point | Low Melting | | Calculated | |
| | fusion | % | Peak Tₘ | Point Peak Tₘ | Peak T_{c} | Density | Density |
| Sample ID | (J/g) | Crystallinity | (° C.) | (° C.) | (° C.) | (g/cm³) | (g/cm³) |
| Example 1 | 156.3 | 53.5 | 116.6 | 111.5 | 106.0 | 0.937** | NM |
| LP2 | 231.7 | 79.3 | 130.0 | NM | 117.7 | NM | 0.967 |
| Example 2 | 161.1 | 55.2 | 121.0 | NM | 109.1 | 0.930** | NM |
| LP1 | 233.4 | 79.9 | 133.5 | NM | 116.6 | NM | 0.965 |
| CE1 | 142.9 | 48.9 | 110.2 | NM | 96.6 | 0.918* | NM |

Note that “NM” designates not measured. Density is taken from the results of Table 3 for LP1 and LP2.
*Calculated using equation 1.
**Calculated using (1/ρ) = ((w₁ /ρ₁) + (w₂/ρ₂)) where ρ = density of the example (g/cm³) and w₁ = weight fraction of CE1 described in Preparation of Example Ethylenic Polymers 1 and 2 for that example and ρ₁ = calculated density for CE1 from equation 1 and w₂ = weight fraction described in Preparation of Example Ethylenic Polymers 1 and 2 of either LP1 or LP2 used for that example and ρ₂ = measured density for either LP1 or LP2 used for that example.

Both ethylenic polymer Examples 1 and 2 have peak melting temperature values between that of Comparative Example 1, which is highly long chain branched ethylene-based polymer made under the same base conditions as Examples 1 and 2, and each of their respective ethylene-based polyethylene Polymers 2 (LP2) and 1 (LP 1). Table 4 shows the highest peak melting temperatures, Tₘ, of the Examples are higher by about 7 to 11° C. and have a greater amount of crystallinity, about 5 to 6 percent, versus Comparative Example 1. Additionally, the peak crystallization temperatures, Tₘ, are about 9 to 12° C. higher than Comparative Example 1, indicating additional benefits in terms of the ability to cool or solidify at a higher temperature than CE1. The DSC Crystallinity results indicate that the ethylenic polymer Examples 1 and 2 have both higher peak melting temperatures and peak crystallization temperatures as well as different heats of fusion values than the comparative example highly long chain branched ethylene-based polymer (Comparative Example 1). Additionally, Examples 1 and 2 also differ in some properties from LP2 and LP1, especially the heat of fusion value. This strongly indicates that Examples 1 and 2 are different from their respective highly long chain branched ethylene-based polymer and ethylene-based polymer components.

FIGS. 3 and 4 show the heat flow versus temperature plots for the ethylenic polymer Examples. Also shown in these figures are the heat flow versus temperature plots for the respective ethylene-based polyethylene LP2 and LP1 and Comparative Example 1.

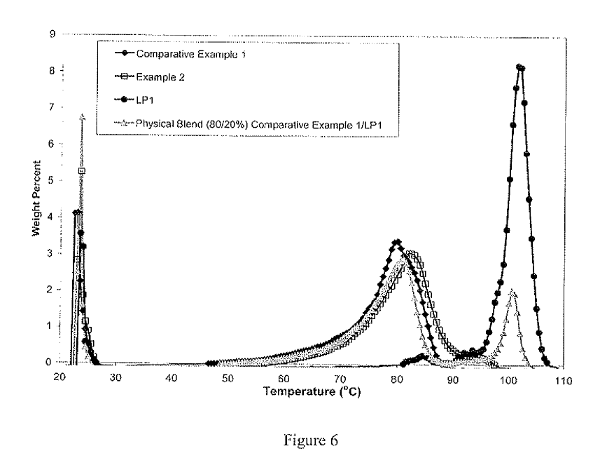

Examples 1 and 2, Comparative Example 1, Polymer 1, and an 80:20 weight ratio physical blend of CE1 and LP I are tested using the Analytical Temperature Rising Elution Fractionation method, provided infra in the Testing Methods section. In FIG. 5, the ATREF runs for Example I and Comparative Example 1 are plotted. In FIG. 6, the ATREF runs for Example 2, Polymer 1 (LP1), Comparative Example 1, and an 80:20 weight ratio physical blend of CE1 and LP1 are plotted. Table 5 gives the percentage of total weight fraction of each polymer sample eluting above 90° C.

TABLE 5
Weight percentage of total polymer eluting
above 90° C. per ATREF analysis.

| | % Weight Fraction |
|---|---|
| Sample ID | Above 90° C. |
| Example 1 | 19.0 |
| Comparative Example 1 | 0.0 |
| Example 2 | 5.3 |
| Physical Blend 80:20 CE 1:LP1 | 17.9 |
| LP1 | 85.2 |

The higher crystallinity of Example 1 relative to Comparative Example 1 is shown by the ATREF plot given in FIG. 5. As shown in FIG. 5, Example 1 has higher temperature melting fractions than Comparative Example 1, the highly branched ethylene-based polymer. More importantly, the ATREF distribution curve of Example 1 shows a relatively homogeneous curve, indicating a generally monomodal crystallinity distribution. If ethylenic polymer Example I is merely a blend of separate components, it could be expected to show a bimodal curve of two blended polymer components. Table 5 also shows that Example 1 has a portion of the polymer which would elute at temperatures at or above 90° C. Comparative Example 1 does not have a portion that elutes at or above 90° C.

The plot of FIG. 6 shows the ATREF plots of Example 2, Polymer I (LP 1), and Comparative Example 1. In comparing the three plots, it is apparent that Example 2 is different than both the highly long chain branched ethylene-based polymer (CEI) and the ethylene-based polymer (LP 1), and not a mere blend. Comparative Example 1 has no elution above 90° C. LPI has a significant amount of material eluting in the 90° C. or above temperature fraction (85.2%), indicating a predominance of the high crystallinity ethylene-based polymer fraction. Example 2, similar to Example 1, shows a relatively homogeneous curve, indicating a relatively narrow crystallinity distribution.

Additionally, a physical blend of an 80:20 weight ratio CE1:LP1 composition is compared against ethylenic polymer Example 2 in FIG. 6. The 80:20 weight ratio physical blend is created to compare to the estimated 27 weight percent ethylene-based polymer LP 1 and balance highly long chain branched ethylene-based polymer composition that comprises Example 2, as stated previously in the Preparation of Example Ethylenic Polymers 1 and 2 section. The ATREF distribution shows the 80:20 weight ratio blend has a well resolved bimodal distribution since it is made as a blend of two distinct polymers. As previously observed, ethylenic polymer Example 2 does not have a bimodal distribution. Additionally, as shown in Table 5, ethylenic polymer Example 2 has a small amount of material eluting in the 90° C. or above temperature fraction (5.3%), whereas the 80:20 weight ratio physical blend has an amount of elution (17.9%) reflective of its high crystallinity ethylene-based polymer fraction.

Triple detector GPC (3D-GPC) using the Gel Permeation Chromatography (GPC) method, provided infra in the Testing Methods section, results are summarized in Table 6.

TABLE 6
Triple detector GPC results, g′, and gpcBR analysis results for Examples 1 and 2,
Comparative Example 1, and a 1MI metallocene polyethylene standard.

| | Conventional GPC | | | | Absolute GPC | | | Mw | | | | |
|---|---|---|---|---|---|---|---|---|---|---|---|---|
| | Mn | Mw | Mz | | Mw | Mz(abs) | | (Abs) | gpcBR | g′ | | |
| Identification | (g/mol) | (g/mol) | (g/mol) | Mw/Mn | (g/mol) | (g/mol) | Mz/Mw | Mw(GPC) | Whole | avg | MH | LCBf |
| Example 1 | 11,950 | 51,570 | 185,200 | 4.32 | 65,180 | 383,800 | 5.89 | 1.26 | 0.53 | 0.765 | 0.534 | 0.853 |
| Comparative Example 1 | 15,480 | 77,920 | 290,400 | 5.03 | 117,660 | 854,600 | 7.26 | 1.51 | 0.89 | 0.716 | 0.464 | 0.973 |
| Example 2 | 16,140 | 74,760 | 198,100 | 4.63 | 96,660 | 327,400 | 3.39 | 1.29 | 0.64 | 0.725 | 0.532 | 0.780 |
| Standard PE | | | | | | | | | | | | |
| (1 MI Metallocene) | 41,350 | 115,630 | 241,100 | 2.80 | 114,430 | 268,500 | 2.35 | 0.99 | 0.01 | 1.000 | 0.701 | 0.000 |

From Table 6 it can be seen that both Examples 1 and 2 show a narrower molecular weight distribution, M_{w}/Mₙ ratio, by conventional GPC than that of the highly long chain branched ethylene-based polymer Comparative Example 1 (5.03 for the control; 4.32 for Example 1; and 4.63 for Example 2). The narrower M_{w}/Mₙ ratio of both Examples can provide benefits in physical properties, improved clarity, and reduced haze over the Comparative Example 1 for film applications. The M_{z}/M_{w} ratio from absolute GPC also distinguishes the ethylenic polymer Examples with narrower values (5.89 and 3.39) and Comparative Example 1 (7.26). The lower M_{z}/M_{w} ratio is associated with improved clarity when used in films. The M_{w}(abs)/M_{w}(GPC) ratio shows that the Examples have lower values (1.26, 1.29) than the Comparative Example 1 (1.51).

In Table 6, branching analysis using both g′ and gpcBR are also included. The g′ value is determined by using the g′ by 3D-GPC method, provided infra in the Testing Methods section. The gpcBR value is determined by using the gpcBR Branching Index by 3D-GPC method, provided infra in the Testing Methods section. The lower gpcBR values for the two ethylenic Examples as compared to Comparative Example 1 and Example 2 indicate comparatively less long chain branching; however, compared to a 1 MI metallocene polymer, there is significant long chain branching in all the compositions.

Preparation of Example Ethylenic Polymers 3-5

### Examples 3-5

This procedure is repeated for each Example. For each example, 2 grams of resin of one of the ethylene-based polymers created in the Preparation of Ethylene-Based Polymers (that is, LP1-3) are added to a 100 ml autoclave reactor. Example 3 is comprised of LP2. Example 4 is comprised of LP1. Example 5 is comprised of LP3. The base properties of these polymers may be seen in Table 3. After closing the reactor, the agitator is turned on at 1000 rpm. The reactor is deoxygenated by pulling vacuum on the system, heating the reactor to 70° C. for one hour, and then flushing the system with nitrogen. After this, the reactor is pressurized with nitrogen and vacuum is pulled on the reactor. This step is repeated three times. The reactor is pressurized with ethylene up to 2000 bar while at ambient temperatures and vented off. This step is repeated three times. On the final ethylene vent, the pressure is dropped only to a pressure of about 100 bar and reactor heating is initiated. When the internal temperature reaches about 220° C., the reactor is then pressurized with ethylene to about 1600 bar and held at 220° C. for at least 30 minutes. The estimated amount of ethylene in the reactor is 46.53 grams. Ethylene is then used to sweep 3.9 nil of a mixture of 0.4321 mmol/ml propionaldehyde and 0.0008645 mmol/ml tert-butyl peroxyacetate initiator in n-heptane into the reactor. Upon sweeping the initiator into the reactor, the pressure is increased within the reactor to about 2000 bar, where free-radical polymerization is initiated. A temperature rise of the reactor to 240° C. is noted. After mixing for 15 minutes, the valve at the bottom of the reactor is opened and the pressure is lowered to between 50-100 bar to begin recovering the resultant polymer. Then the reactor is repressurized to 1600 bar, stirred for 3 minutes, and then the valve at the bottom is opened to again lower the pressure to between 50-100 bar. For each Example, a total of about 6 grams of product polymer is recovered from the reactor. Based upon the conversion value of ethylene in the reactor, each Example is comprised of about 33% weight percent ethylene-based polymer and about 67% weight percent highly long chain branched ethylene-based polymer formed during the free radical polymerization.

### Comparative Example 2

Free-radical polymerization of ethylene under the same process conditions as given in Examples 3-5 without the addition of any ethylene-based polymer yields 4.64 grams of a highly long chain branched ethylene-based polymer designated as Comparative Example (CE) 2. Because no comonomer is used, Comparative Example 2 is an ethylene homopolymer. A temperature increase during the free radical reaction to 275° C. is noted.

Characterization of Example Ethylenic Polymers 3-5

Ethylenic polymer Examples 3-5 are tested using both the DSC Crystallinity and Fast Temperature Rising Elution Fractionation methods, provided infra in the Testing Methods section. The results of the testing of Examples 3-5 are compared to similar test results of Comparative Example 2, Polymers 1-3 (LP1-3), and physical blends of Comparative Example 2 with Polymers 1-3. The results are shown in Table 7.

TABLE 7
DSC analysis of Example 3-5, Polymers 1-3 (LP1-3), Comparative
Example 2, and individual physical blends of LP1-3 and CE2.

| | Low | High | | | |
|---|---|---|---|---|---|
| | Melting | Melting | Heat of | Calculated | |
| | Point Peak | Point Peak | Fusion | Density | Density |
| Sample | Tₘ (° C.) | Tₘ (° C.) | (J/g) | (g/cm³) | (g/cm³) |
| Comparative | NM | 110.7 | 148.7 | 0.921* | NM |
| Example 2 | | | | | |
| LP2 | NM | 130.0 | 239.5 | NM | 0.967 |
| Example 3 | 113.6 | 124.7 | 166.2 | 0.936** | NM |
| Blend 67:33 | 109.5 | 127.0 | 178.1 | NM | NM |
| CE2:LP2 | | | | | |
| LP1 | NM | 132.4 | 230.3 | NM | 0.965 |
| Example 4 | 110.2 | 124.9 | 163.7 | 0.935** | NM |
| Blend 67:33 | 109.5 | 128.9 | 173.9 | NM | NM |
| CE2:LP1 | | | | | |
| LP3 | NM | 134.1 | 209.9 | NM | 0.958 |
| Example 5 | 111.4 | 123.8 | 158.5 | 0.933** | NM |
| Blend 67:33 | 109.0 | 129.4 | 170.9 | NM | NM |
| CE2:LP3 | | | | | |

Note that “NM” designates not measured. Density values are taken from Table 3 for P1, P2, P3. Calculated Density for comparative example 2 is determined using Equation 1.
*Calculated using equation 1.
**Calculated using (1/ρ) = ((w₁/ρ₁ + (w₂/ρ₂)) where ρ = density of the example (g/cm³) and w₁ = weight fraction of CE2 described in Preparation of Example Ethylenic Polymers 3-5 for that example and ρ₁ = calculated density for CE2 from equation 1 and w₂ = weight fraction described in Preparation of Example Ethylenic Polymers 3-5 of either LP1 or LP2 or LP3 used for that example and ρ₂ = measured density for either LP1 or LP2 or LP3 used for that example.

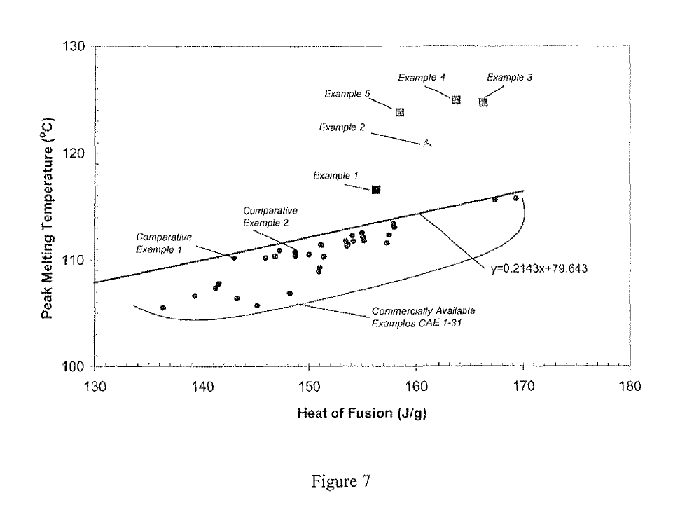

Using data from Tables 3, 4, and 7, a comparison plot between peak melting temperature (Tₘ) and heat of fusion (H_{f}) comparing Examples 1-5, Comparative Examples 1 and 2, and Commercial Available Resins 1-30 can be made to find relative relationships, such as the relationship shown in FIG. 7. Note in the case of materials with multiple melting temperatures, the peak melting temperature is defined as the highest melting temperature. FIG. 7 reveals that all five of the Examples demonstrate different functional properties from the group created by the Comparative Examples and the Commercially Available Resins.

Due to the separation between the five ethylenie polymer Examples and the group formed from the two Comparative Examples and the Commercially Available Resins, a line of demarcation between the groups to emphasize the difference may be established for a given range of heats of fusion. A numerical relationship, Equation 15, may be used to represent such a line of demarcation:

Tₘ(° C.)=(0.2143*H_{f}(J/g))+79.643 (Eq. 15).

For such a relationship line, all five ethylenic polymer Examples have at least a high melting point peak Tₘ equal to, if not greater than, a determined peak melting temperature using Equation 15 for a given heat of fusion value. In contrast, all of the Comparative Examples and Commercially Available Resins are below the relationship line, indicating their peak melting temperatures are less than a determined peak melting temperatures using Equation 15 for a given heat of fusion value.

Numerical relationships, Equations 16 and 17, may also be used to represent such a line of demarcation based upon the relationships between the Examples, Comparative Examples, and Commercially Available Resins as just discussed:

Tₘ(° C.)=(0.2143*H_{f}(J/g))+81 (Eq. 16),

More preferably Tₘ(° C.)=(0.2143*H_{f}(J/g))+85 (Eq. 17).

Tables 4 and 7 reveal a heat of fusion range for the Example ethylenic polymers. The heat of fusion of the ethylenic polymers are from about 120 to about 292 J/g, preferably from about 130 to about 170 J/g.

Tables 4 and 7 also show a peak melting temperature range for the Example ethylenic polymers. The peak melting temperature of the ethylenic polymers are equal to or greater than about 100° C., and preferably from about 100 to about 130° C.

Ethylenic polymer Examples 3-5 and Comparative Example 2, are tested using the Nuclear Magnetic Resonance method, provided infra in the Testing Methods section, to show comparative instances of short chain branching. The results are shown in Table 8.

TABLE 8
Nuclear Magnetic Resonance analysis for short chain branching distribution
in samples of Comparative Example 2 and ethylenic polymers Examples 3-5.

| Sample | C1 | C2 | C3 | C4 | C5 | C6+ |
|---|---|---|---|---|---|---|
| Comparative Ex. 2 | 0.85 | 1.04 | 0.18 | 7.30 | 2.17 | 0.72 |
| Ex. 3 | ND | 0.42 | ND | 3.70 | 1.68 | 0.40 |
| Ex. 4 | ND | 0.35 | ND | 4.41 | 1.68 | 0.30 |
| Ex. 5 | ND | 0.50 | ND | 4.61 | 1.46 | 0.62 |

For Table 8, “Cx” indicates the branch length in branches/1000 total carbons (C1=methyl, C5=amyl branch, etc.). “ND” stands for a result of none detected or observed at the given limit of detection.

Ethylene-based polymers LP1-3, although tested, are not included in the results of Table 8 because LP1-3 did not exhibit C1-C6+branching. This is expected as LP 1-3 are high crystallinity ethylene-based polymers that do not have any comonomer content that would produce short-chain branches in the range tested.

As observed in Table 8, the ethylenic polymer Examples 3-5 show no appreciable C1 (methyl) or C3 (propyl) branching and C2, C4, and C5 branching compared to Comparative Example 2. “Appreciable” means that the particular branch type is not observed above the limits of detection using the Nuclear Magnetic Resonance method (about 0.1 branches/1000 carbons), provided infra in the Testing Methods section. Comparative Example 2, a product of free-radical branching, shows significant branching at all ranges. In some embodiment ethylenic polymers, the ethylenic polymer has no “appreciable” propyl branches. In some embodiment ethylenic polymers, the ethylenic polymer has no appreciable methyl branches. In some embodiment ethylenic polymers, at least 0.1 units of amyl groups per 1000 carbon atoms are present. In some embodiment ethylenic polymers, no greater than 2.0 units of amyl groups per 1000 carbon atoms are present.

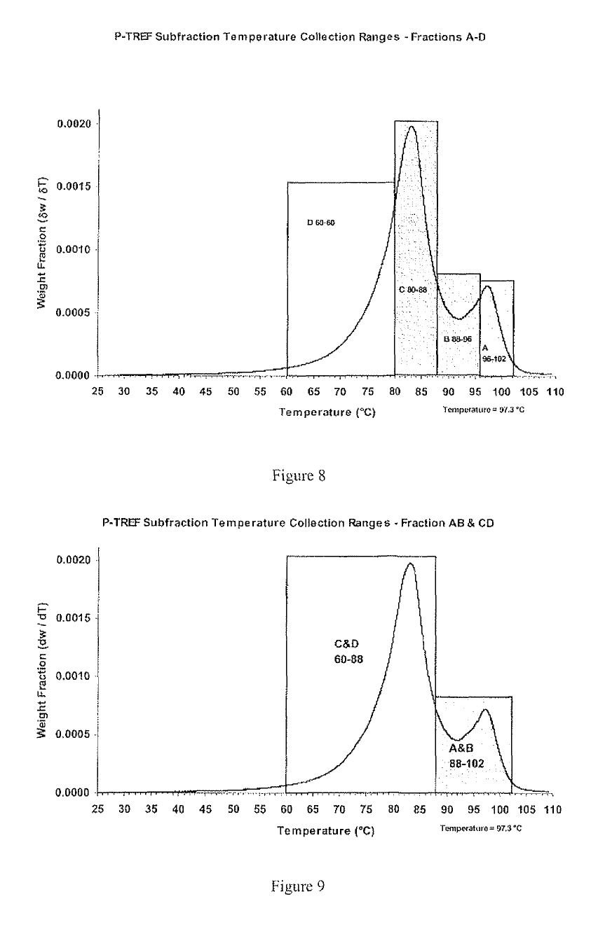

Samples of Examples 3-5 are separated into subfractions using the Preparative Temperature Rising Elution Fractionation method, provided infra in the Testing Methods section. The subfractions are combined into four fractions, Fractions A-D, before the solvent is removed and the polymers are recovered. FIG. 8 represents the temperature splits for Fractions A-D using the method on Examples 3-5.

The Fractions are analyzed for weight and their weight average temperature determined. Table 9 summarizes the weight fraction distribution of Examples 3-5 as well as Comparative Example 2 and gives each Fraction its designation A-D.

TABLE 9
Weight fraction percent and fraction weight average
temperature for fractions of Examples 3-5.

| | | Weight | Fraction |
|---|---|---|---|
| | | Fraction | Weight Average |
| Sample ID | Fraction | (wt %) | Temperature (° C.) |
| Example 3 | A | 11.27 | 98.5 |
| | B | 11.32 | 93.1 |
| | C | 50.03 | 84.0 |
| | D | 27.38 | 73.1 |
| Example 4 | A | 15.76 | 98.4 |
| | B | 12.53 | 93.1 |
| | C | 46.80 | 83.9 |
| | D | 24.91 | 73.4 |
| Example 5 | A | 17.90 | 98.4 |
| | B | 17.79 | 93.4 |
| | C | 35.81 | 84.2 |
| | D | 28.50 | 71.5 |

As can be seen in Table 9, Examples 3-5 have a significant amount of polymer eluting at a weight average temperature greater than 90° C. For all three ethylenic polymer

Examples there is at least one preparative TREF fraction that elutes at 90° C. or greater (Fraction A and Fraction B). For all three ethylenic polymer Examples at least 7.5% of the ethylenic polymer elutes at a temperature of 90° C. or greater based upon the total weight of the ethylenic polymer (Example 3: 22.59 wt %; Example 4: 28.29 wt %; Example 5: 25.69 wt %). For all three ethylenic polymer Examples at least one preparative TREF fraction elutes at 95° C. or greater (Fraction A). For all three ethylenic polymer Examples at least 5.0% of the ethylenic polymer elutes at a temperature of 95° C. or greater based upon the total weight of the ethylenic polymer (Example 3: 11.27 wt %; Example 4: 15.76 wt %; Example 5: 17.90 wt %).

Some of the Fractions are analyzed by triple detector GPC, and g′ and gpcBR values are determined using the g′ by 3D-GPC and gpcBR Branching Index by 3D-GPC methods, provided infra in the Testing Methods section. Comparative Example 2, Polymers 1-3 (LP 1-3), and representative weight ratio physical blends based upon the estimated composition of Examples 3-5 of respective Polymers and Comparative Example 2 are analyzed. The results are shown in Table 10.

TABLE 10
Analysis using 3D-GPC for molecular weights, distributions, and moments, g', and gpcBR for select Fractions of Examples 3-5,
Polymers 1-3 (LP1-3), and blends of LP1-3 and CE2.

| | Conventional GPC | | | | Absolute GPC | | | | | | | |
|---|---|---|---|---|---|---|---|---|---|---|---|---|
| | Mn | Mw | Mz | | Mw | Mz (abs) | | Mw (Abs) | | | | |
| | (g/mol) | (g/mol) | (g/mol) | Mw/Mn | (g/mol) | (g/mol) | Mz/Mw | Mw (GPC) | gpcBR | g′ avg | MH | LCBf |
| Comparative | 10,840 | 46,840 | 151,600 | 4.32 | 65,170 | 615,000 | 9.44 | 1.39 | 0.49 | 0.768 | 0.574 | 3.88 |
| Example 2 | | | | | | | | | | | | |
| LP2 | 5,950 | 17,100 | 32,600 | 2.87 | 16,450 | 34,700 | 2.11 | 0.96 | 0.02 | 1.000 | 0.670 | 0 |
| Example 3 | 12,590 | 57,930 | 155,200 | 4.60 | 84,060 | 627,700 | 7.47 | 1.45 | 0.34 | 0.820 | 0.600 | 2.771 |
| Example 3 P-Tref | 12,330 | 32,760 | 235,800 | 2.66 | 38,400 | 205,500 | 5.35 | 1.17 | 0.17 | 0.907 | 0.440 | 0.93 |
| Fraction 98.5° C. | | | | | | | | | | | | |
| Fraction | | | | | | | | | | | | |
| Example 3 P-Tref | 7,480 | 26,210 | 103,700 | 3.50 | 49,610 | 621,700 | 12.53 | 1.89 | 0.27 | 0.862 | 0.636 | 2,767 |
| Fraction 93.1° C. | | | | | | | | | | | | |
| Fraction | | | | | | | | | | | | |
| Blend 67:33 | 8,850 | 36,030 | 123,900 | 4.07 | 47,390 | 494,800 | 10.44 | 1.32 | 0.379 | 0.844 | 0.551 | 0.963 |
| CE 2/LP 2 | | | | | | | | | | | | |
| LP1 | 16,250 | 35,600 | 61,500 | 2.19 | 36,110 | 66,500 | 1.84 | 1.01 | 0.01 | 1.000 | 0.702 | 0 |
| Example 4 | 19,530 | 80,880 | 197,200 | 4.14 | 100,170 | 496,500 | 4.96 | 1.24 | 0.30 | 0.829 | 0.625 | 1.704 |
| Example 4 P-Tref | 15,780 | 50,050 | 120,600 | 3.17 | 74,240 | 247,100 | 3.33 | 1.48 | 0.31 | 0.842 | 0.621 | 0.779 |
| Fraction 93.1° C. | | | | | | | | | | | | |
| Fraction | | | | | | | | | | | | |
| Example 4 P-Tref | 14,020 | 58,390 | 126,800 | 4.16 | 93,850 | 1,370,100 | 14.6 | 1.61 | 0.30 | 0.806 | 0.621 | 1.939 |
| Fraction 83.9° C. | | | | | | | | | | | | |
| Fraction | | | | | | | | | | | | |
| Blend 67:33 | 11,930 | 43,730 | 141,800 | 3.67 | 57,280 | 393,700 | 6.87 | 1.31 | 0.36 | 0.845 | 0.519 | 3.087 |
| CE 2/LP 1 | | | | | | | | | | | | |
| LP3 | 31,390 | 72,970 | 131,300 | 2.32 | 72,370 | 125,900 | 1.74 | 0.99 | -0.01 | 1.000 | 0.671 | 0 |
| Example 5 | 18,980 | 90,500 | 210,400 | 4.77 | 122,830 | 616,700 | 5.02 | 1.36 | 0.39 | 0.789 | 0.627 | 2.206 |
| Example 5 P-Tref | 18,640 | 74,780 | 141,100 | 4.01 | 116,940 | 2,172,200 | 18.58 | 1.56 | 0.38 | 0.778 | 0.606 | 1.188 |
| Fraction 93.4° C. | | | | | | | | | | | | |
| Fraction | | | | | | | | | | | | |
| Blend 67:33 | 12,130 | 54,140 | 135,900 | 4.46 | 69,260 | 329,500 | 4.76 | 1.28 | 0.263 | 0.855 | 0.626 | 2.495 |
| CE 2/LP 3 | | | | | | | | | | | | |

Table 10 show strong evidence of bonding between the ethylene-based polymers LP1-3 and the highly long chain branched ethylene-based polymer fanned in the reactor to form ethylenic polymers Examples 3-5. This can be seen in the absolute GPC molecular weight. Comparing the molecular weight averages from both conventional and absolute GPCs of the Examples with their respective physical blends as listed in Table 10 show the detected average molecular weights for the Examples are much higher than the blends, indicating chemical bonding.

The evidence of reaction is also strongly supported by the long chain branching indices. All the gpcBR values for the Examples show the presence of long chain branching in the high-temperature P-TREF Fractions (Fractions A and B), which would usually be the temperature range reflective of high crystallinity and lack of LCBs. For ethylene-based polymers LP1-3, the gpcBR value is at or near zero since they do not have any long chain branching. In addition, ethylene-based polymers such as LP 1-3 typically give a g′ index close to 1.0 and an MH exponent close to 0.72. As the level of long chain branching increases, the g′ index decreases from the value of 1.0; the MH exponent decreases from 0.72; and the gpcBR index increases from the value of 0. Conventional highly long chain branched ethylene-based polymer, such as CE2, does not produce a fraction with both high crystallinity and high levels of long chain branching.

In analyzing the samples for methyls per 1000 carbons, it is necessary to combine Fractions into Fractions AB and CD to perform the Methyls per 1000 Carbons

Determination on P-TREF Fractions procedure, provided infra in the Testing Methods section due to the small sample size. Fractions A and B are combined to give Fraction AB and Fractions C and D are combined to give Fraction CD. The new weight average temperatures for Fractions AB and CD are calculated in accordance with Equation 3.

FIG. 9 represents the temperature splits for combined Fractions AB and CD of

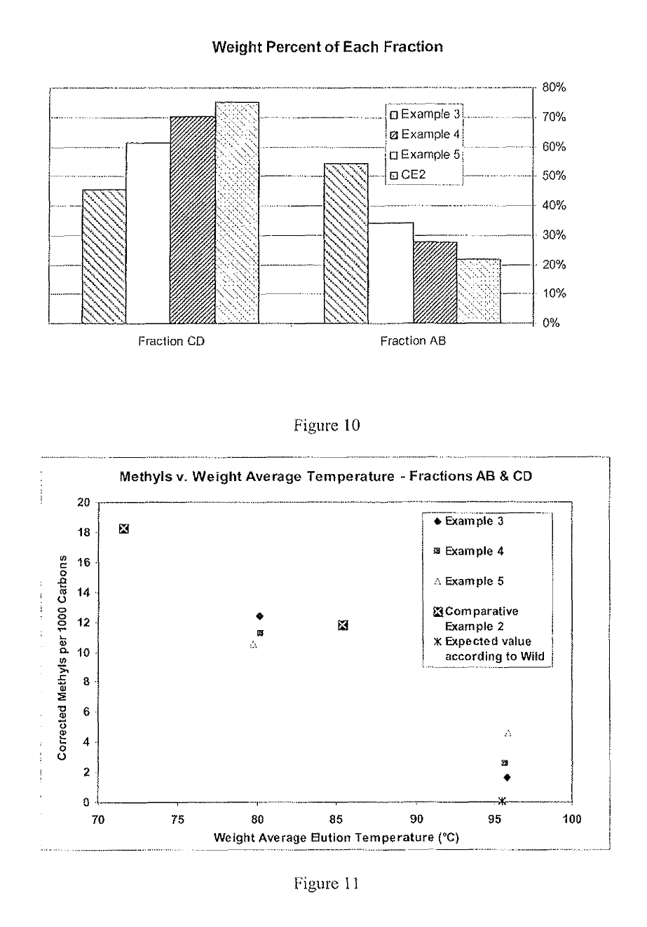

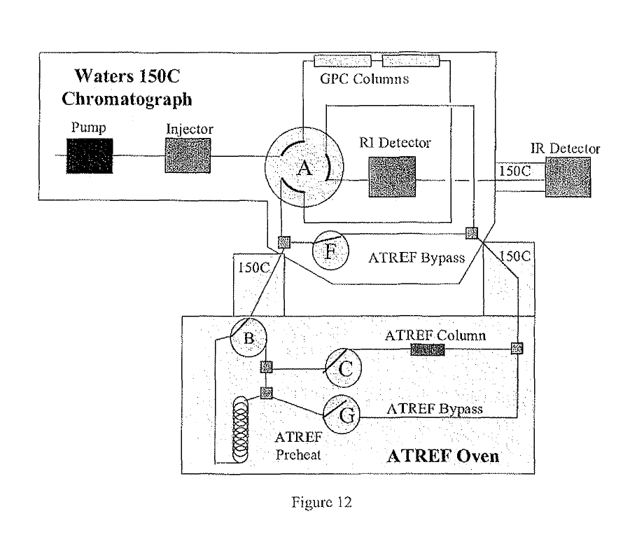

Examples 3-5. FIG. 10 and Table 11 show the two larger Fractions and their weight fraction as a percentage of the whole polymer. Table 11 and FIG. 11 show the methyls per 1000 carbon results.

TABLE 11
Weight Fraction and Fraction Weight Average Temperature for Fractions of Examples 3-5.

| | | | | Fraction | | | | Fraction |
|---|---|---|---|---|---|---|---|---|
| | | Fraction | | CD | | Fraction | | AB |
| | Fraction CD | CD | Fraction | Corrected | Fraction AB | AB | Fraction | Corrected |
| | Temperature | Weight | CD Mₙ | Methyls/ | Temperature | Weight | AB | Methyls/ |
| Sample ID | (° C.) | Fraction | (GPC) | 1000 C. | (° C.) | Fraction | Mₐ (GPC) | 1000° C. |
| Example 3 | 80.15 | 0.77 | 18,288 | 12.4 | 95.80 | 0.23 | 17,562 | 1.6 |
| Example 4 | 80.29 | 0.72 | 33,760 | 11.2 | 96.02 | 0.28 | 33,515 | 2.6 |
| Example 5 | 78.57 | 0.64 | 24,470 | 10.5 | 95.90 | 0.36 | 58,201 | 4.6 |

Examples 3-5 show relatively high levels of branching in the high temperature fraction, Fraction AB, as indicated by the methyls per thousand values. FIG. 11 is a plot of methyls per 1000 carbons (corrected for end groups or methyls) versus weight average elution temperature as determined by Methyls per 1000 Carbons Determination on P-TREF Fractions analysis of Fractions AB and CD for Examples 3-5 using the data from Table 11. The high temperature Fractions of the ethylenic polymer Examples have higher than expected methyls per thousand carbons—higher numbers than would be expected from merely a linear ethylene-based polymer.

The results of Fast Temperature Rising Elution Fractionation testing shown in Table 12 also indicate strong evidence of long chain branching and grafting in Examples 3-5. This can be seen in the LS-90 measured M_{w} shown. Comparing the M_{w} of the Examples with their respective blends, the M_{w} of the respective Examples are all much higher than the respective blends.

TABLE 12
F-TREF results for Examples 3-5, Comparative Example
2, LP1-3, and several representative physical blends.

| | f-TREF Low-Melting Peak | | f-TREF High-Melting Peak | |
|---|---|---|---|---|
| | Peak Temp. | LS-90 | Peak Temp. | LS-90 |
| Sample | (° C.) | Mw | (° C.) | Mw |
| Comparative | 76.39 | 64,073 | ND | ND |
| Example 2 | | | | |
| LP2 | ND | ND | 93.18 | 17,191 |
| Example 3 | 78.85 | 75,779 | 91.38 | 73,073 |
| Blend 67:33 | 75.29 | 47,532 | 92.52 | 46,766 |
| CE 2/LP2 | | | | |
| LP1 | ND | ND | 94.87 | 33,888 |
| Example 4 | 80.61 | 90,571 | 92.88 | 87,853 |
| Blend 67:33 | 75.40 | 50,157 | 93.85 | 50,128 |
| CE 2/LP1 | | | | |
| LP3 | ND | ND | 95.37 | 69,209 |
| Example 5 | 79.59 | 101,326 | 91.46 | 107,875 |
| Blend 67:33 | 75.27 | 46,459 | 94.49 | 56,928 |
| CE 2/LP3 | | | | |

Note that “ND” means not determined.

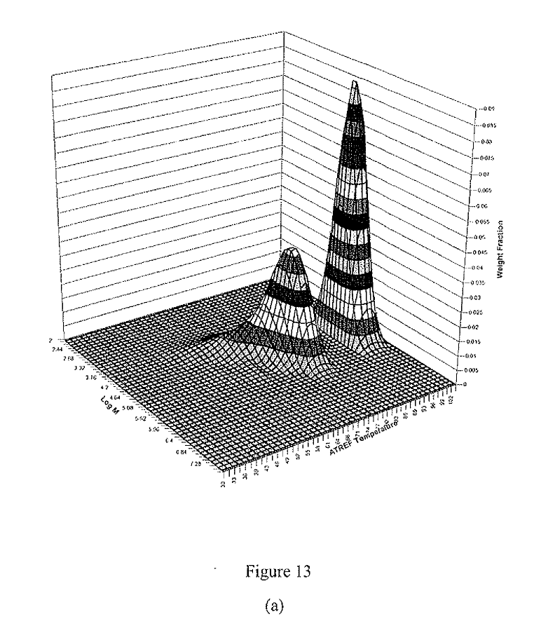

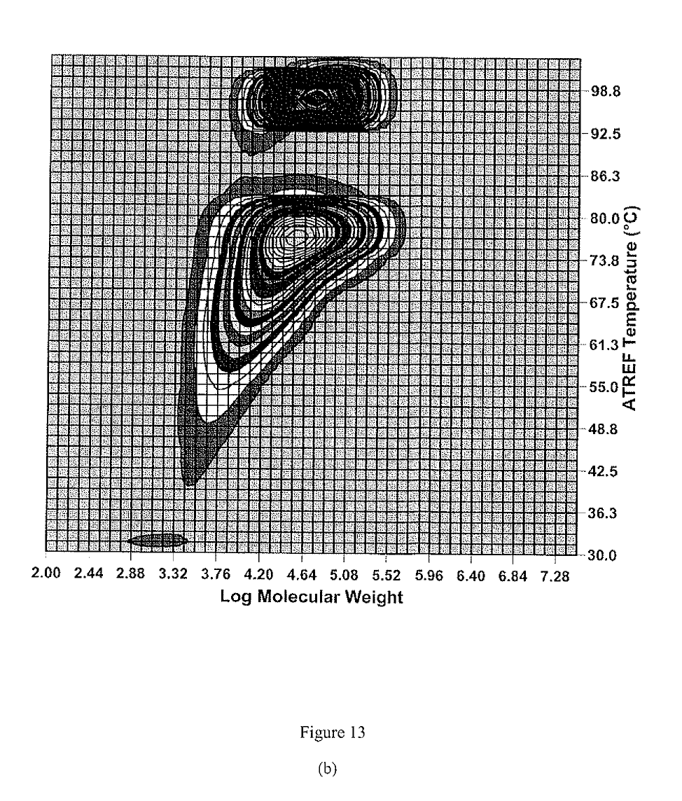

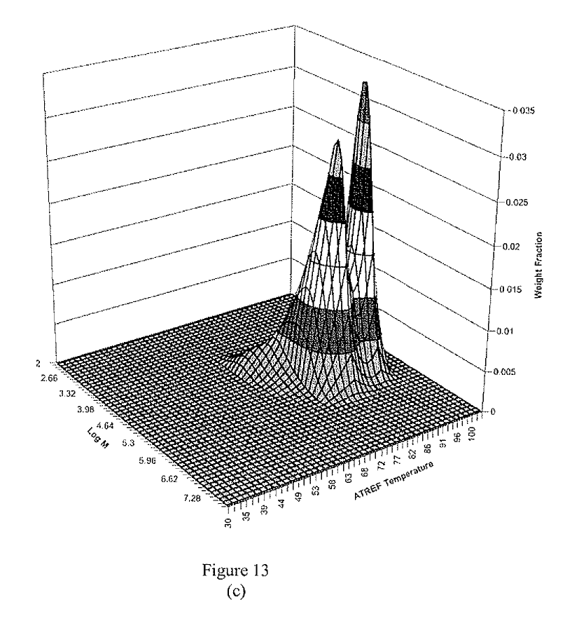

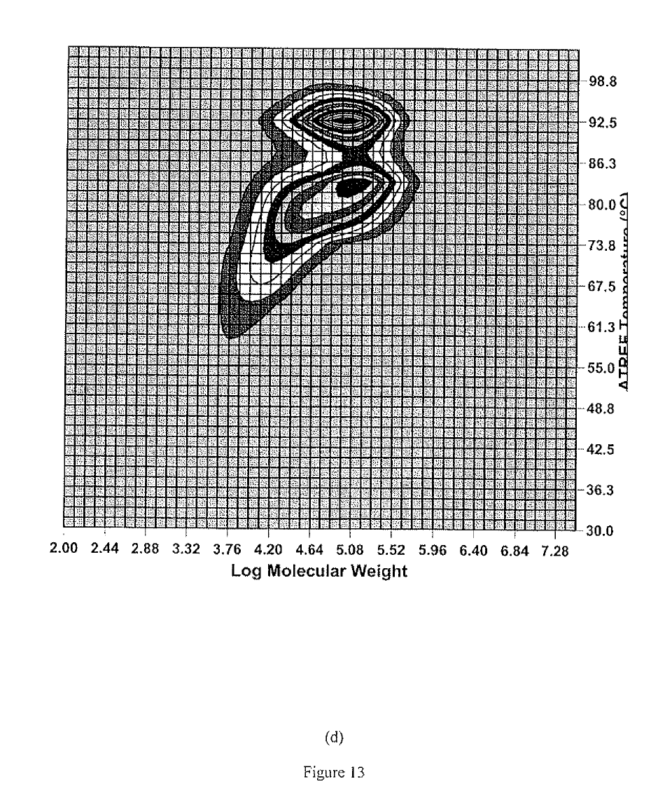

FIGS. 13(a) and 13(b) show a 3D and 2D IR response curve, respectively, cross fractionation result for a Polymer 3 (LP3) and Comparative Example 2 33:67 weight ratio physical blend based upon the Cross-Fractionation by TREF method, provided infra in the Testing Methods section. FIGS. 13(c) and 13(d) show the IR response curve using the same method for Example 5 (which incorporates Polymer 3 (LP3)). FIGS. 13(a), (c), and (d) have a z-axis (Weight Fraction) in increments of 0.02, represented not only by grid lines (3D view only) but also by color bands (both 3D and 2D view). The z-axis increments for Weight Fraction in FIG. 13(b) are set at 0.05 to assist in viewing the 2D representation.

Comparing the two sets of graphs, it can clearly be seen that the blend components of FIGS. 13(a) and 13(b) are well resolved into two distinct “islands” of temperature elution versus molecular weight, indicating the bimodal nature of the blend. FIGS. 13(c) and 13(d) show Example 5 and how the ethylenic polymer does not completely resolve, indicating a single polymeric material. Also noteworthy is that the molecular weights of the components of the blend are significantly lower than the corresponding constituents of Example 5, which can be observed by comparing FIG. 13(b) with FIG. 13(d).

The following prophetic examples further illustrate the invention. Unless otherwise indicated, all parts and percentages are by weight.

### Specific Embodiments

### Example A

A monolayer 15 mil thick protective film is made from a blend comprising 80 wt % of Example 1, 20 wt % of a maleic anhydride (MAH) modified ethylene/1-octene copolymer (ENGAGE® 8400 polyethylene grafted at a level of about 1 wt % MAH, and having a post-modified MI of about 1.25 g/10 min and a density of about 0.87 glee), 1.5 wt % of Lupersol® 101, 0.8 wt % of tri-allyl cyanurate, 0.1 wt % of Chimassorb® 944, 0.2 wt % of Naugard® P, and 0.3 wt % of Cyasorb® UV 531. The melt temperature during film formation is kept below about 120° C. to avoid premature crosslinking of the film during extrusion. This film is then used to prepare a solar cell module. The film is laminated at a temperature of about 150° C. to a superstrate, e.g., a glass cover sheet, and the front surface of a solar cell, and then to the back surface of the solar cell and a baekskin material, e.g., another glass cover sheet or any other substrate. The protective film is then subjected to conditions that will ensure that the film is substantially crosslinked.

### Example B

The procedure of Example A is repeated except that the blend comprised 90 wt % Example 2 and 10 wt % of a maleic anhydride (MAH) modified ethylene/1-octene (ENGAGE® 8400 polyethylene grafted at a level of about 1 wt % MAH, and having a post-modified MI of about 1.25 g/10 min and a density of about 0.87 g/cc), and the melt temperature during film formation was kept below about 120° C. to avoid premature crosslinking of the film during extrusion.

### Example C

The procedure of Example A is repeated except that the blend comprised 97 wt % Example 2 and 3 wt % of vinyl silane (no maleic anhydride modified ENGAGE® 8400 polyethylene), and the melt temperature during film formation was kept below about 120° C. to avoid premature crosslinking of the film during extrusion.

### Formulations and Processing Procedures:

Step 1: Use ZSK-30 extruder with Adhere Screw to compound resin and additive package with or without Amplify.

Step 2: Dry the material from Step 2 for 4 hours at 100 F maximum (use W&C canister dryers).

Step 3: With material hot from dryer, add melted DiCup+Silane+TAC, tumble blend for 15 min and let soak for 4 hours.

TABLE 13
Formulation

| Sample No. | 1 |
|---|---|
| Example 2 | 94.7 |
| 4-Hydroxy-TEMPO | 0.05 |
| Cyasorb UV 531 | 0.3 |
| Chimassorb 944 LD | 0.1 |
| Tinuvin 622 LD | 0.1 |
| Naugard P | 0.2 |
| Additives below added via soaking step | |
| Dicup-R Peroxide | 2 |
| Gamma-methacrylo-propyl-trimethoxysilane | 1.75 |
| (Dow Corning Z-6030) | |
| Sartomer SR-507 Tri-Allyl Cyanurate (TAC) | 0.8 |
| Total | 100 |

### Test Methods and Results:

The adhesion with glass is measured using silane-treated glass. The procedure of glass treatment is adapted it from a procedure in Gelest, Inc. “Silanes and Silicones, Catalog 3000 A”.

Approximately 10 mL of acetic acid is added to 200 mL of 95% ethanol in order to make the solution slightly acidic. Then, 4 mL of 3-aminopropyltrimethoxysilane is added with stirring, making a ˜2% solution of silane. The solution sits for 5 minutes to allow for hydrolysis to begin, and then it is transferred to a glass dish. Each plate is immersed in the solution for 2 minutes with gentle agitation, removed, rinsed briefly with 95% ethanol to remove excess silane, and allowed to drain. The plates are cured in an oven at 110° C. for 15 minutes. Then, they are soaked in a 5% solution of sodium bicarbonate for 2 minutes in order to convert the acetate salt of the amine to the free amine. They are rinsed with water, wiped dry with a paper towel, and air dried at room temperature overnight.

The method for testing the adhesion strength between the polymer and glass is the 180 peel test. This is not an ASTM standard test, but it is used to examine the adhesion with glass for PV modules. The test sample is prepared by placing uncured film on the top of the glass, and then curing the film under pressure in a compression molding machine. The molded sample is held under laboratory conditions for two days before the test. The adhesion strength is measured with an Instron machine. The loading rate is 2 in/min, and the test is run under ambient conditions. The test is stopped after a stable peel region is observed (about 2 inches). The ratio of peel load over film width is reported as the adhesion strength.

Several important mechanical properties of the cured films are evaluated using tensile and dynamic mechanical analysis (DMA) methods. The tensile test is run under ambient conditions with a load rate of 2 in/min, The DMA method is conducted from −100 to 120° C.

The optical properties are determined as follows: Percent of light transmittance is measured by UV-vis spectroscopy. It measures the absorbance in the wavelength of 250 nm to 1200 nm. The internal haze is measured using ASTM DI003-61.

The results are reported in Table 14. The EVA is a fully formulated film available 1from Etimex.

TABLE 14
Test Results

| Key Properties | EVA |
|---|---|
| Elongation to break (%) | 411.7 |
| STDV* | 17.5 |
| Tensile strength at 85° C. (psi) | 51.2 |
| STDV* | 8.9 |
| Elongation to break at 85° C. (%) | 77.1 |
| STDV* | 16.3 |
| Adhesion with glass (N/mm) | 7 |
| % of transmittance | >97 |
| STDV* | 0.1 |
| Internal Haze | 2.8 |
| STDV* | 0.4 |

*STDV = Standard Deviation.

The adhesion with glass is measured using silane-treated glass. The procedure of glass treatment is adapted it from a procedure in Gelest, Inc. “Silanes and Silicones, Catalog 3000 A”:

Approximately 10 mL of acetic acid is added to 200 mL of 95% ethanol in order to make the solution slightly acidic. Then, 4 mL of 3-aminopropyltrimethoxysilane is added with stirring, making a ˜2% solution of silane. The solution sits for 5 minutes to allow for hydrolysis to begin, and then it is transferred to a glass dish. Each plate is immersed in the solution for 2 minutes with gentle agitation, removed, rinsed briefly with 95% ethanol to remove excess silane, and allowed to drain. The plates are cured in an oven at 110° C. for 15 minutes. Then, they are soaked in a 5% solution of sodium bicarbonate for 2 minutes in order to convert the acetate salt of the amine to the free amine. They are rinsed with water, wiped dry with a paper towel, and air dried at room temperature overnight.

The optical properties are determined as follows: Percent of light transmittance is measured by UV-vis spectroscopy. It measures the absorbance in the wavelength of 250 nm to 1200 nm. The internal haze is measured using ASTM D1003-61.

### Example D

### Polyethylene-Based Encapsulant Film

Example 3 is used and several additives are selected to add functionality or improve the long term stability of the resin. They are UV absorbent Cyasorb UV 531, UV-stabilizer Chimassorb 944 LD, antioxidant Tinuvin 622 LD, vinyltrimethoxysilane (VTMS), and peroxide Luperox-101. The formulation in weight percent is described in Table 15.

TABLE 15
Film Formulation

| Formulation | Weight Percent |
|---|---|
| Example 3 | 97.34 |
| Cyasorb UV 531 | 0.3 |
| Chimassorb 944 LD | 0.1 |
| Tinuvin 622 LD | 0.1 |
| Irganox-168 | 0.08 |
| Silane (Dow Corning Z-6300) | 2 |
| Luperox-101 | 0.08 |
| Total | 100 |

Sample Preparation

Example 3 pellets are dried at 40° C. for overnight in a dryer. The pellets and the additives are dry mixed and placed in a drum and tumbled for 30 minutes. Then the silane and peroxide are poured into the drum and tumbled for another 15 minutes. The well-mixed materials are fed to a film extruder for film casting.

Film is cast on a film line (single screw extruder, 24-inch width sheet die) and the processing conditions are summarized in Table 16.

TABLE 16
Process Conditions

| | | | Extruder Die | | | | | | |
|---|---|---|---|---|---|---|---|---|---|
| Sample | | | Head P | Zone 1 | Zone 2 | Zone 3 | Adapter | Adapter | Die |
| # | RPM | Amp | (psi) | (° F.) | (° F.) | (° F.) | (° F.) | (° C.) | (° C.) |
| 1 | 25 | 22 | 2,940 | 300 | 325 | 350 | 350 | 182 | 140 |

An 18-19 mil thick film is saved at 5.3 feet per minute (ft/min). The film sample is sealed in an aluminum bag to avoid UV-irradiation and moisture.

Test Methods and Results 1. Optical Property:

The light transmittance of the film is examined by UV-visible spectrometer (Perkin Elmer UV-Vis 950 with scanning double monochromator and integrating sphere accessory). Samples used for this analysis have a thickness of 15 mils.

2. Adhesion to Glass:

The method used for the adhesion test is a 180° peel test. This is not an ASTM standard test, but has been used to examine the adhesion with glass for photovoltaic module and auto laminate glass applications. The test sample is prepared by placing the film on the top of glass under pressure in a compression molding machine. The desired adhesion width is 1.0 inch. The frame used to hold the sample is 5 inches by 5 inches. A Teflon™ sheet is placed between the glass and the material to separate the glass and polymer for the purpose of test setup. The conditions for the glass/film sample preparation are:
(1) 160° C. for 3 minutes at 80 pounds per square inch (psi) (2000 lbs)
(2) 160° C. for 30 minutes at 320 psi (8000 lbs)
(3) Cool to room temperature at 320 psi (8000 lbs)
1(4) Remove the sample from the chase and allow 48 hours for the material to condition at room temperature before the adhesion test.

The adhesion strength is measured with a materials testing system (Instron 5581). The loading rate is 2 inches/minutes and the tests are run at ambient conditions (24° C. and 50% RH). A stable peel region is needed (about 2 inches) to evaluate the adhesion to glass. The ratio of peel load in the stable peel region over the film width is reported as the adhesion strength.

The effect of temperature and moisture on adhesion strength is examined using samples aged in hot water (80° C.) for one week. These samples are molded on glass, then immersed in hot water for one week. These samples are then dried under laboratory conditions for two days before the adhesion test. In comparison, the adhesion strength of the same commercial EVA film as described above is also evaluated under the same conditions. The adhesion strength of the experimental film and the commercial sample are shown in Table 17.

TABLE 17
Tests Results of Adhesion to Glass

| | Conditions for | | Adhesion |
|---|---|---|---|
| Sample | Molding on | Aging | Strength |
| Information | Glass | Condition | (N/mm) |
| Commercial Film | 160° C., one hr | none | 10 |
| (cured) | | | |
| Commercial Film | 160° C., one hr | 80° C. in water | 1 |
| (cured) | | for one week | |

3. Water Vapor Transmission Rate (WVTR):

The water vapor transmission rate is measured using a permeation analysis instrument (Mocon Permatran W Model 101 K). All WVTR units are in grams per square meter per day (g/(m²-day)) measured at 38° C. and 50° C. and 100% RH, an average of two specimens. The commercial EVA film as described above is also tested to compare the moisture barrier properties. The commercial film thickness is 15 mils, and is cured at 160° C. for 30 minutes. The results of WVTR testing are reported in Table 18.

TABLE 18
Summary of WVTR Test Results

| | | | | | | Permeation |
|---|---|---|---|---|---|---|
| | | WVTR at | WVTR at | | Permeation | at 50° C. |
| | | 38° C. | 50° C. | Thick | at 38° C. (g- | (g-mil)/ |
| Film | Specimen | g/(m²-day) | g/(m²-day) | (mil) mil | mil)/(m²-day) | (m²-day) |
| Com- | A | 44.52 | 98.74 | 16.80 | 737 | 1660 |
| mercial Film | B | 44.54 | 99.14 | 16.60 | 749 | 1641 |
| | avg. | 44.53 | 98.94 | 16.70 | 743 | 1650 |

### Example E

Two resins are used to prepare a three-layer A-B-A, co-extruded film for encapsulating an electronic device. The total thickness of the film is 18 mil. The outer A layers contact the surfaces of the die. The core (B) layer comprises 80 volume percent (vol %) of the sheet, and each outer layer comprises 10 vol % of the sheet. The composition of the A layers does not require drying. The composition of the core layer, i.e., the B layer, comprises the same components and is prepared in the same manner as the composition described in Example C. In the skin layers, a blend of (i) Example 2 and (ii) AMPLIFY GR 216 resin (a MAH-modified ethylene/1-octene resin grafted at a level of about 1 wt % MAH), and having a post-modified MI of about 1.25 g/10min and a density of about 0.87 g/cc. Both compositions are reported in Table 19.

TABLE 19
Compositions of the Layers of an A-B-A Layer Film

| | Outer Layers | Core Layer |
|---|---|---|
| Component | (wt %) | (wt %) |
| Example C | 0 | 94.7 |
| Example 2 | 20 | 0 |
| AMPLIFY^{tm} GR-216O | 79.3 | 0 |
| TEMPO | 0 | 0.05 |
| Cyasorb UV 531 | 0.3 | 0.3 |
| Chimassorb 944 LD | 0.1 | 0.1 |
| Tinuvin 622 LD | 0.1 | 0.1 |
| Naugard P | 0.2 | 0.2 |
| Dicup-R | 0 | 2.0 |
| Trimethoxysilane | 0 | 1.75 |
| Sartomer SR-507 | 0 | 0.8 |

The A-B-A film is co-extruded onto an electronic device, and the film exhibits improved optical properties in terms of percent transmittance and internal haze relative to a monolayer of either composition.

### Example F

Two set of samples are prepared to demonstrate that UV absorption can be shifted by using different UV-stabilizers. Example 4 is used and Table 20 reports the formulations with different UV-stabilizers (all amounts are in weight percent). The samples are made using a mixer at a temperature of 190° C. for 5 minutes. Thin films with a thickness of 16 mils are made using a compressing molding machine. The molding conditions are 10 minutes at 160° C., and then cooling to 24° C. in 30 minutes. The UV spectrum is measured using a UV/Vis spectrometer such as a Lambda 950. The results show that different types (and/or combinations) of UV-stabilizers can allow the absorption of UV radiation at a wavelength below 360 nm.

TABLE 20
Example 4 with Different UV-Stabilizers

| | Example | Absorber | Cyasorb | Cyasorb | Chimassorb | Chimassorb | Tinuvin |
|---|---|---|---|---|---|---|---|
| Sample | 4 | UV-531 | UV2908 | UV3529 | UV-119 | 944-LD | 622-LD |
| 1 | 100 | | | | | | |
| 2 | 99.7 | 0.3 | | | | | |
| 3 | 99.7 | | 0.3 | | | | |
| 4 | 99.7 | | | 0.3 | | | |
| 5 | 99.7 | | | | 0.3 | | |
| 6 | 99.5 | | | | | 0.25 | 0.25 |
| 7 | 99.85 | 0.15 | | | | | |

Another set of samples are prepared to examine UV-stability. Again, Example 4 is selected for this study. Table 21 reports the formulations designed for encapsulant polymers for photovoltaic modules with different UV-stabilizers, silane and peroxide, and antioxidant. These formulations are designed to lower the UV absorbance and at the same time maintain and improved the long term UV-stability.

TABLE 21
Example 4 with Different UV-Stabilizers, Silanes, Peroxides and Antioxidants

| | Example | Absorber | Cyasorb | Cyasorb | Univil | Doverphos | Hostavin | Chimassorb | Chimassorb | Tinuvin | Western | Irgafos |
|---|---|---|---|---|---|---|---|---|---|---|---|---|
| Samples | 4 | UV 531 | UV 2908 | UV 3529 | 4050 | S-9228 | N30 | UV 119 | 944 LD | 622 LD | 399 | 166 |
| C 1 | 99.8 | | | | | | | | | | 0.2 | |
| C 2 | 99.3 | 0.3 | | | | | | | 0.1 | 0.1 | 0.2 | |
| C 3 | 99.5 | 0.3 | | | | | | | 0.1 | 0.1 | | |
| 1 | 99.5 | | 0.5 | | | | | | | | | |
| 2 | 99.5 | | | 0.5 | | | | | | | | |
| 3 | 99.5 | | | | | | | 0.5 | | | | |
| 4 | 99.5 | | | | | | | | 0.5 | | | |
| 5 | 99.7 | | | 0.3 | | | | | | 0.5 | | |
| 6 | 99.3 | | | 0.7 | | | | | | | | |
| 7 | 99.5 | | | | 0.5 | | | | | | | |
| 8 | 99.5 | | | | | | 0.5 | | | | | |
| 9 | 99.4 | 0.3 | | | | 0.1 | | | 0.1 | 0.1 | | |
| 10 | 99.3 | 0.3 | | | | | | | 0.1 | 0.1 | | 0.2 |
| 11 | 99.3 | | | 0.5 | | | | | | | | 0.2 |

Although the invention has been described in considerable detail through the preceding description and examples, this detail is for the purpose of illustration and is not to be construed as a limitation on the scope of the invention as it is described in the appended claims. All United States patents, published patent applications and allowed patent applications identified above are incorporated herein by reference.

What is claimed is:

1. An electronic device module comprising:
A. at least one electronic device, and
B. a polymeric material in intimate contact with at least one surface of the electronic device, the polymeric material comprising
(1) an ethylenic polymer comprising at least 0.1 amyl branches per 1000 carbon atoms as determined by Nuclear Magnetic Resonance and both a highest peak melting temperature, Tₘ, in ° C., and a heat of fusion, H_{f}, in J/g, as determined by DSC Crystallinity, where the numerical values of Tₘ and H_{f} correspond to the relationship:
Tₘ≧(0.2143*H_{f})+79.643,
and wherein the ethylenic polymer has less than about 1 mole percent hexene comonomer, and less than about 0.5 mole percent butene, pentene, or octene comonomer.
(2) optionally, free radical initiator or a photoinitiator in an amount of at least about 0.05 wt % based on the weight of the copolymer,
(3) optionally, a co-agent in an amount of at least about 0.05 wt % based upon the weight of the copolymer, and
(4) optionally, a vinyl silane compound.

2. The module of claim 1 in which the electronic device is a solar cell.

3. The module of claim 1 in which the free radical initiator is present.

4. The module of claim 3 in which the free radical initiator is a peroxide.

5. The module of claim 1 in which the polymeric material is in the form of a monolayer film in intimate contact with at least one face surface of the electronic device.

6. The module of claim 1 further comprising at least one glass cover sheet.

7. The module of claim 1 which the polymeric material further comprises a polyolefin polymer grafted with an unsaturated organic compound containing at least one ethylenic unsaturation and at least one carbonyl group.

8. The module of claim 7 in which the unsaturated organic compound is maleic anhydride.

9. An electronic device module comprising:
A. at least one electronic device, and
B. a polymeric material in intimate contact with at least one surface of the electronic device, the polymeric material comprising
(1) an ethylenic polymer comprising at least one preparative TREF fraction that elutes at 95° C. or greater using a Preparative Temperature Rising Elution Fractionation method, where at least one preparative TREF fraction that elutes at 95° C. or greater has a branching level greater than about 2 methyls per 1000 carbon atoms as determined by Methyls per 1000 Carbons Determination on P-TREF Fractions, and where at least 5 weight percent of the ethylenic polymer elutes at a temperature of 95° C. or greater based upon the total weight of the ethylenic polymer,
(2) optionally, a vinyl silane in an amount of at least about 0.1 wt % based on the weight of the copolymer,
(3) free radical initiator in an amount of at least about 0.05 wt % based on the weight of the copolymer, and
(4) optionally, a co-agent in an amount of at least about 0.05 wt % based on the weight of the copolymer.

10. The module of claim 9 in which the electronic device is a solar cell.

11. The module of claim 9 in which the free radical initiator is present.

12. The module of claim 11 in which the free radical initiator is a peroxide.

13. The module of claim 9 in which the vinyl silane is present and is at least one of vinyl tri-ethoxy silane and vinyl tri-methoxy silane.

14. The module of claim 13 in which the free radical initiator is a peroxide.

15. The module of claim 9 in which the polyolefin copolymer is crosslinked such that that the copolymer contains less than about 70 percent xylene soluble extractables as measured by ASTM 2765-95.

16. The module of claim 9 in which the polymeric material is in the form of a monolayer film in intimate contact with at least one face surface of the electronic device.

17. The module of claim 9 further comprising at least one glass cover sheet.

18. The module of claim 9 in which the polymeric material further comprises a polyolefin polymer grafted with an unsaturated organic compound containing at least one ethylenic unsaturation and at least one carbonyl group.

19. The module of claim 18 in which the unsaturated organic compound is maleic anhydride.

20. An electronic device module comprising:
A. at least one electronic device, and
B. a polymeric material in intimate contact with at least one surface of the electronic device, the polymeric material comprising
(1) an ethylenic polymer comprising at least one preparative TREF fraction that elutes at 95° C. or greater using a Preparative Temperature Rising Elution Fractionation method, where at least one preparative TREF fraction that elutes at 95° C. or greater has a gpcBR value greater than 0.05 and less than 5 as determined by gpcBR Branching Index by 3D-GPC, and where at least 5 weight percent of the ethylenic polymer elutes at a temperature of 95° C. or greater based upon the total weight of the ethylenic polymer,
(2) optionally, free radical initiator or a photoinitiator in an amount of at least about 0.05 wt % based on the weight of the copolymer,
(3) optionally, a co-agent in an amount of at least about 0.05 wt % based upon the weight of the copolymer, and
(4) optionally, a vinyl silane compound.
